(19) United States
(12) Patent Application Publication
(10) Pub. No.: US 2024/0369933 A1
(43) Pub. Date: Nov. 7, 2024

(54) MATERIALS AND METHODS FOR DRY RESIST TECHNOLOGY

(71) Applicant: THE JOHNS HOPKINS UNIVERSITY, Baltimore, MD (US)

(72) Inventors: David Howard Fairbrother, Baltimore, MD (US); Peter Corkery, Baltimore, MD (US); Patrick Eckhert, Baltimore, MD (US); Michael Tsapatsis, Baltimore, MD (US); Kayley Waltz, Baltimore, MD (US)

(21) Appl. No.: 18/654,821

(22) Filed: May 3, 2024

Related U.S. Application Data
(60) Provisional application No. 63/499,876, filed on May 3, 2023.

(51) Int. Cl. G03F 7/16; G03F 7/004; G03F 7/20

(52) U.S. Cl. CPC G03F 7/167; G03F 7/0042; G03F 7/2047

(57) ABSTRACT

The present disclosure relates to the dry deposition of thin, amorphous metal-imidazolate resist films via molecular layer deposition and the dry removal of patterned resists using β-diketonate-type compounds to produce an extreme ultraviolet (EUV) resist process that allows for more environmentally friendly, cost-effective, and high-resolution resist development.

### CROSS-REFERENCE TO RELATED APPLICATION

This application claims priority to U.S. Provisional Application No. 63/499,876 filed on May 3, 2023, the contents of which are herein incorporated by reference.

### FEDERALLY SPONSORED RESEARCH OR DEVELOPMENT

This invention was made with government support under grant DE-SC0021212 awarded by the Department of Energy. The government has certain rights in the invention.

### TECHNICAL FIELD

The present disclosure relates to the dry deposition of resists via direct molecular layer deposition of amorphous metal-imidazolate thin films and the dry removal of patterned resists using β-diketonate-type compounds. This process is practical such that it will produce an extreme ultraviolet (EUV) resist without the need for solvents, which allows for more cost-effective and high-resolution resist development for potential applications within the semiconductor industry.

### BACKGROUND

Photolithography resists are used to transfer circuit patterns to the surface of a silicon substrate on which the resist is deposited. In extreme ultraviolet lithography (EUVL), projection of 13.5-nm (92 eV) light through a photomask exposes selected areas of the photoresist to EUV photons, initiating chemical reactions within these areas (Silverman et al., 2005; Wu et al., 2007). For commercial resists, these reactions change the solubility of the resist in certain solvents, allowing for the patterned areas to be selectively removed (positive tone resist) or to remain (negative tone resist) following subsequent solvent rinses in the development step. These resists are deposited via spin-coating, wherein a solution containing the resist is deposited on a rapidly spinning wafer, leading to a large amount of wasted resist and solvent, which must be chemically treated. Spin coating of films with thicknesses amenable to EUV lithography (<40 nm) can be complicated by inconsistent film quality over the coated area where nanometer scale variability represents a significant fraction of the resist height. Following the spin-coating step, the solvent must be removed from the coated resist in a pre-bake step. Furthermore, capillary forces during development in liquids can result in pattern collapse, limiting the pattern resolution and maximum aspect ratio. Thus, there is a need for improved methods for developing photoresists.

### SUMMARY

The presently disclosed subject matter relates to the dry deposition of resists via molecular layer deposition of amorphous metal-imidazolate thin films and the dry removal of patterned resists using β-diketonate-type compounds to produce an EUV resist process that allows for more cost-effective, solvent free, and high-resolution resist development.

In one aspect, the direct molecular layer deposition of an amorphous metal-imidazolate thin film using organometallic and organic precursors comprising a zinc-imidazolate based film is described.

In another aspect, a method for patterning metal-imidazolate thin films is described, wherein the films are directly deposited by molecular layer deposition and comprise a zinc-imidazolate based film, wherein the method comprises either the formation of submicron scale patterns through direct write patterning with an electron source or shadow mask patterning with an x-ray or extreme ultraviolet, or maskless and shadow mask patterning with an electron, x-ray, extreme ultraviolet, or other irradiation source capable of producing secondary electrons with an energy sufficient to cause chemical changes in the film to demonstrate chemical transformation of the film on larger scales more amenable to analysis.

In still another aspect, a method for the dry etching of patterned films is described, wherein the method comprises loading thin films, wherein the films were directly deposited by molecular layer deposition and comprise a zinc-imidazolate based film, into a reactor after irradiation and exposing them to a gaseous β-diketonate to leave behind a film in only the irradiated areas. This technology is practical for potential application as a dry extreme ultraviolet lithography (EUVL) resist.

Certain aspects of the presently disclosed subject matter having been stated hereinabove, which are addressed in whole or in part by the presently disclosed subject matter, other aspects will become evident as the description proceeds when taken in connection with the accompanying Examples and Drawings as best described herein below.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

Having thus described the presently disclosed subject matter in general terms, reference will now be made to the accompanying Drawings, which are not necessarily drawn to scale, and wherein:

FIG. 1A illustrates a schematic of the presently disclosed atomic/molecular layer deposition system showing positions of precursor cylinders and major equipment with heating zones outlined;

FIG. 1B shows a photo of the oven, 2 mIm precursor cylinder, and reactor with lid removed;

FIG. 1C shows a photo of the mass flow controller, diethylzinc (DEZ) and H₂O precursor cylinders, and diaphragm valves for dosing precursors;

FIG. 2A illustrates a schematic of the vapor etching system showing positions of etchant and equipment with heating zones outlined;

FIG. 2B illustrates a schematic of the vapor etching system showing positions of etchant cylinder, argon line with a mass flow controller, and equipment with heating zones outlined;

FIG. 3A shows film thickness observed by ellipsometry as a function of cycle numbers at temperatures of between about 100° C. to about 175° C. for the deposition of ZnmIm films using DEZ and 2 mIm as precursors;

FIG. 3B shows growth per cycle observed by ellipsometry as a function of the duration of the argon purge following DEZ and 2 mIm pulses;

FIG. 3C shows film thickness observed by ellipsometry as a function of cycle numbers at temperatures of between about 100° C. to about 175° C. for the deposition of ZnIca films using DEZ and Ica as precursors;

FIG. 4 shows XRD spectra of metal-imidazolate film deposited via molecular layer deposition, ALD ZnO, and ZIF-8 film formed by ligand vapor treatment of ALD ZnO;

FIG. 5A illustrates the ALD/MLD process to form a metal-imidazolate film from DEZ and 2 mIm;

FIG. 5B shows a suggested sequence of layer-by-layer growth during the ALD/MLD process;

FIG. 6A shows AFM height mapping of a patterned film after dry etching with Hfac-H at 120° C. for 15 minutes. The electron beam irradiation was conducted at 2 kV, 0.1 nA, and an electron dose of 16 mC cm⁻². The scale bar is 1 μm;

FIG. 6B is a line-scan profile across the marked trace in FIG. 6A;

FIG. 6C shows AFM height mapping of a patterned film after dry etching with Hfac-H under argon flow at 120° C. for 30 minutes. The electron beam irradiation was conducted at 2 kV, 0.1 nA, and an electron dose of 10 mC cm⁻². The scale bar is 1 μm;

FIG. 6D is a line-scan profile across the marked trace in FIG. 6C;

FIG. 6E shows AFM height mapping of a patterned film after dry etching with Hfac-H under argon flow at 120° C. for 30 minutes. The electron beam irradiation was conducted at 2 kV, 0.1 nA, and an electron dose of 20 mC cm⁻². The scale bar is 1 μm;

FIG. 6F is a line-scan profile across the marked trace in FIG. 6D;

FIG. 7 illustrates the overall process schematic of the all-vapor phase deposition and patterning of MLD metal-imidazolate films. A home-built reactor with precursors DEZ and 2 mIm is used to directly deposit metal-imidazolate films. These films are patterned by electron beam irradiation followed by dry etching with Hfac-H, a model β-diketonate, to produce volatile products Zn(Hfac)₂ and 2 mIm;

FIG. 8 is a top-view SEM image of a patterned film after dry etching with Hfac-H at 120° C. for 15 minutes. The electron beam irradiation was conducted at 2 kV, 0.1 nA, with electron doses of 8 mC cm², 12 mC cm⁻², and 16 mC cm⁻² (top to bottom). The scale bar is 5 m;

FIG. 9A is a TEM image of a patterned film on a 15-nm thick silicon nitride TEM support after dry etching with Hfac-H at 120° C. for 30 minutes with argon flow. The electron beam irradiation was conducted at 5 kV, 0.1 nA, and electron doses of 10 mC cm⁻². The nominal line width was set to be 10 nm with 250 nm spacing between the outer edges of each line. The resulting line patterns are approximately 30 nm wide. The scale bar is 2 μm;

FIG. 9B is a TEM image of a patterned film on a 15-nm thick silicon nitride TEM support after dry etching with Hfac-H at 120° C. for 30 minutes with argon flow. The electron beam irradiation was conducted at 5 kV, 0.1 nA, and electron doses of 10 mC cm⁻². The nominal line width was set to be 20 nm with 250 nm spacing between the outer edges of each line. The resulting line patterns are approximately 40 nm wide. The scale bar is 2 μm;

FIG. 9C is a TEM image of a patterned film on a 15-nm thick silicon nitride TEM support after dry etching with Hfac-H at 120° C. for 30 minutes with argon flow. The electron beam irradiation was conducted at 5 kV, 0.1 nA, and electron doses of 10 mC cm⁻². The nominal line width was set to be 50 nm with 250 nm spacing between the outer edges of each line. The resulting line patterns are approximately 50 nm wide. The scale bar is 2 μm;

FIG. 10A shows the XPS spectra of 60-nm thick ZnmIm films and ZIF-8 films grown from 60-nm thick ZnmIm films after deposition, after dry etching with Hfac-H at 120° C. for 60 minutes, and after both irradiation at an accelerating voltage of 2 kV and dry etching with Hfac-H at 120° C. for 60 minutes;

FIG. 10B shows the IR spectra of 60-nm thick ZnmIm films as compared to crystalline ZIF-8 films grown from a 60-nm thick ZnmIm film;

FIG. 11A shows AFM height mapping of a 100 nm pitch dot pattern with dots 25 nm in diameter after dry etching with Hfac-H at 120° C. for 30 minutes. The electron beam irradiation was conducted at 30 kV, ˜165 pA, and an electron dose of 200 mC cm⁻². The scale bar is 200 nm;

FIG. 11B shows AFM height mapping of a pattern with 29 nm wide and 250 nm pitch lines after dry etching with Hfac-H at 120° C. for 30 minutes. The electron beam irradiation was conducted at 30 kV, ˜165 pA, and an electron dose of 200 mC cm⁻². The scale bar is 500 nm;

FIG. 11C is a line-scan profile across the marked trace in FIG. 11B;

FIG. 11D shows AFM height mapping of a line spacing gradient pattern with the numbers on top of the image representing the line pitch in nm. The lines are all approximately 29 nm wide after dry etching with Hfac-H at 120° C. for 30 minutes. The electron beam irradiation was conducted at 30 kV, approximately 165 pA, and an electron dose of 200 mC cm⁻². The scale bar is 1 μm;

FIG. 12A is a TEM image of a patterned film on a 15-nm thick silicon nitride TEM support after dry etching with Hfac-H at 120° C. for 30 minutes with argon flow. The electron beam irradiation was conducted at 20 kV, 0.1 nA, and an electron dose of 80 mC cm⁻². The nominal line width was set to be 20 nm with 250 nm spacing between the outer edges of each line. The resulting line patterns are approximately 25 nm wide. The scale bar is 2 μm;

FIG. 12B is a TEM image of a patterned film on a 15-nm thick silicon nitride TEM support after dry etching with Hfac-H at 120° C. for 30 minutes with argon flow. The electron beam irradiation was conducted at 30 kV, 0.1 nA, and an electron dose of 40 mC cm⁻². The nominal line width was set to be 20 nm and the resulting line patterns are approximately all 22 nm wide. The scale bar is 2 μm on the image and 500 nm on the inset;

FIG. 13A demonstrates transfer of patterned features into the Si substrate using an Oxford Fluorine ICP RIE Etching system. It shows a three-dimensional AFM projection of a film before (left) and after (right) plasma etching using an Oxford Provided ‘Submicron Si Etch” recipe for 15 seconds with process gasses SF₆ and C₄F₈; and

FIG. 13B is a SEM image showing a variety of other patterns transferred into the silicon surface after plasma etching.

### DETAILED DESCRIPTION

The presently disclosed subject matter now will be described more fully hereinafter with reference to the accompanying Drawings, in which some, but not all embodiments of the inventions are shown. Like numbers refer to like elements throughout. The presently disclosed subject matter may be embodied in many different forms and should not be construed as limited to the embodiments set forth herein; rather, these embodiments are provided so that this disclosure will satisfy applicable legal requirements. Indeed, many modifications and other embodiments of the presently disclosed subject matter set forth herein will come to mind to one skilled in the art to which the presently disclosed subject matter pertains having the benefit of the teachings presented in the foregoing descriptions and the associated Drawings. Therefore, it is to be understood that the presently disclosed subject matter is not to be limited to the specific embodiments disclosed and that modifications and other embodiments are intended to be included within the scope of the appended claims.

As provided hereinabove, current methods for developing photoresists have several limitations. These limitations have motivated research into dry (solvent-free) methods that utilize, deposit, and selectively remove patterned resists in the vapor phase. These processes could greatly reduce the materials cost of resists and improve throughput by obviating the need for a pre-bake step. Furthermore, vapor-phase deposition and development reduce or eliminate the need for breaking vacuum during the patterning process, reducing potential sources of contamination that may be otherwise introduced during solvent-based coating and development. Inorganic-organic hybrid materials deposited via molecular layer deposition could incorporate elements with much higher photoabsorption cross-section at 92 eV than carbon (Fallica et al., 2018), eliminating the need for chemical amplifiers commonly employed in traditional organic polymer resists (Kuznetsova et al., 2020). Additionally, dry deposition avoids issues associated with liquid resist solutions, which can be susceptible to changes in performance after prolonged storage resulting in limited shelf life.

The present disclosure addresses the pressing need in the field for discovering a completely solvent-free resist technology with increased sensitivity compared to traditional resist materials to create patterned resists with nanometer size features.

### A. Direct Molecular Layer Deposition of an Amorphous Metal-Imidazolate Thin Film

Broadly, in one embodiment, direct molecular layer deposition of an amorphous metal-imidazolate film comprising a zinc-imidazolate based film is described wherein organometallic and organic precursors are used. In this method, the organic imidazole type ligand interacts with the metal-based precursor. The amorphous metal-imidazolate films are relevant for applications including, but not limited to, extreme ultraviolet lithography (EUVL) resists and other microelectronics. Furthermore, the material produced by irradiation that is not removed via etching may be used in applications including, but not limited to, structural materials, dielectric barriers, and photomasks in subsequent processing steps.

More particularly, in some embodiments, the presently disclosed subject matter provides a method for vapor phase deposition of a non-crystalline thin film having a chemical formula of MLₐ on a substrate, wherein M is a metal ion, L is a ligand, and n is a number of ligands, the method comprising:
pulsing a first precursor comprising an organometallic compound including the metal ion and a second precursor comprising the ligand sequentially into a flow-through reactor to create an organometallic vapor and a ligand vapor, and contacting the organometallic vapor and the ligand vapor with the substrate to form a non-crystalline thin film having the chemical formula of MLₙ on the substrate.

In certain embodiments, the metal ion is Zn⁺². In certain embodiments, n is 2 when the metal ion has a charge of +2. In particular embodiments, the organometallic compound comprising the first precursor is selected from diethylzinc (DEZ), dimethylzinc, zinc(II) bis(1,1,1,5,5,5-hexafluoro-2,4-pentanedionate), zinc(II) bis(2,2,6,6-tetramethyl-3,5-heptanedionate), and zinc(II) bis(2,4-pentanedionate).

In certain embodiments, the ligand comprises an imidazolate. In certain embodiments, the imidazolate is a derivative of 1,3-diazacyclopenta-2,4-diene having a chemical C₃N₂HR₃, wherein the R groups are positioned at the 1, 4, and 5 positions of 1,3-diazacyclopenta-2,4-diene and are each independently selected from —H, —CH₃, —CH₂CH₃, —Cl, —Br, —I, —C₄H₄, and —CHO. In particular embodiments, the imidazolate is a conjugate base of, i.e., is derived from, an imidazole selected from:

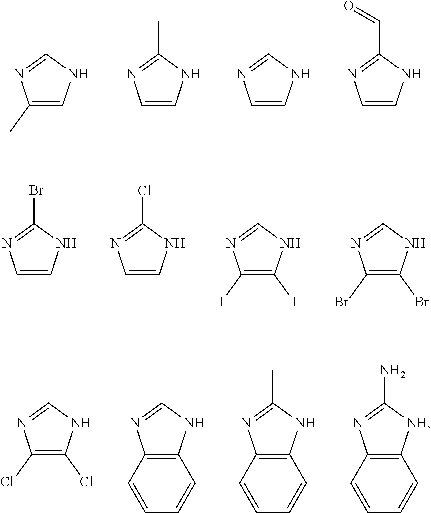

and combinations thereof.

In certain embodiments, the flow-through reactor is maintained at a temperature between about 100° C. to about 250° C., including about 100, 110, 115, 120, 125, 130, 135, 140, 145, 150, 155, 160, 165, 170, 175, 180, 185, 190, 195, 200, 205, 210, 215, 220, 225, and 250° C., preferably at a temperature between about 125° C. to about 175° C., including about 125, 130, 135, 140, 145, and 150° C., and more preferably at a temperature of about 150° C.

In certain embodiments, the method further comprises purging the flow-through reactor with an inert gas between sequential pulses of the first precursor and the second precursor to remove one or more byproducts, one or more unreacted precursors, and combinations thereof. In certain embodiments, the inert gas has a flow rate of about 10 standard cubic centimeters per minute. In certain embodiments, the inert gas comprises Argon. In certain embodiments, the flow-through reactor is maintained at a pressure between about 100 mTorr to about 1,000 mTorr, including about 100, 150, 200, 250, 300, 350, 400, 450, 500, 550, 600, 650, 700, 750, 800, 850, 900, 950, and 1,000 mTorr.

In certain embodiments, the first precursor has a pulse length of about 50 ms and the second precursor has a pulse length between about 50 to about 1,000 ms, including about 50, 60, 70, 80, 90,100,150, 200, 250, 300, 350, 400, 450, 500, 550, 600, 650, 700, 750, 800, 850, 900, 950, and 1,000 ms. In certain embodiments, the first precursor has a purge length between about 5 s to about 60 s, including about 5, 10, 15, 20, 25, 30, 35, 40, 45, 50, 55, and 60 s, and the second precursor has a purge length between about 10 s to about 90 s, including about 10, 20, 30, 40, 50, 60, 70, 80, and 90 s.

In certain embodiments of the method, the thin film comprises a zinc-imidazolate film. In particular embodiments, the zinc-imidazolate film comprises a Zn⁺² metal ion and a 2-methylimidazole (2 mIm) ligand.

In some embodiments of this method, the deposited metal-imidazolate film has a roughness of less than 1 nm and a lack of long-range order, as evidenced by XRD. In some embodiments, the film thickness is linearly related to the number of deposition cycles, as expected for ALD/MLD processes.

In some embodiments, the deposited metal-imidazolate film is achieved with a thickness of about 2 nm to about 500 nm, including about 2, 3, 4, 5, 6, 7, 8, 9, 10, 11, 12, 13, 14, 15, 20, 25, 30, 35, 40, 45, 50,100,150, 200, 250, 300, 350, 400, 450, and 500 nm, and in some embodiments, in the range of about 4 nm to about 15 nm, including about 4, 5, 6, 7, 8, 9, 10, 11, 12, 13, 14, and 15 nm.

### B. Patterning Metal-Imidazolate Thin Films

In another embodiment, a method for patterning metal-imidazolate thin films, wherein the films are directly deposited by molecular layer deposition and comprise a zinc-imidazolate based film is described.

In another embodiment, a method for patterning metal-imidazolate thin films, wherein the films are directly deposited by molecular layer deposition and comprise a zinc-imidazolate based film, is described, wherein the method comprises either the formation of submicron scale patterns through direct write patterning with an electron source or shadow mask patterning with an x-ray or extreme ultraviolet, or maskless and shadow mask patterning with an electron, x-ray, extreme ultraviolet, or other irradiation source capable of producing secondary electrons with an energy sufficient to cause chemical changes in the film to demonstrate chemical transformation of the film on larger scales more amenable to analysis.

More particularly, in some embodiments, the presently disclosed subject matter provides a method for patterning a thin film on a substrate, the method comprising:
(a) providing a thin film as prepared by the method described immediately hereinabove;
(b) loading the thin film into a high vacuum chamber; and
(c) patterning the thin film with direct write patterning, maskless patterning, or shadow mask patterning.

In certain embodiments, the presently disclosed methods further comprises irradiating the thin film with an electron source, an x-ray source, an extreme ultraviolet source, or other radiation source capable of producing secondary electrons. In certain embodiments, the method comprises patterning by an electron beam having an acceleration voltage with a range from about 2 keV to about 200 keV, including about 2, 3, 4, 5, 6, 6, 8, 9, 10, 20, 30, 40, 50, 60, 70, 80, 90,100,110, 120, 130, 140, 150, 160, 170, 180, 190, and 200 keV. In particular embodiments, the method comprises patterning by an electron beam having a current with a range from about 6.3 pA to about 1.2 nA, including about 6.3, 10, 20, 30, 40, 50,100, 200, 300, 400, 500, 600, 700, 800, 900, 1000, 1100, and 1200 pA. In particular embodiments, the method comprises patterning by an electron beam having a dosage with a range from about 0.01 mC cm⁻² to about 50 mC cm², including about 0.01, 0.05, 0.1, 0.5, 1, 2, 3, 4, 5, 6, 7, 8, 9, 10, 15, 20, 25, 30, 35, 40, 45, and 50 cm⁻²

In certain embodiments, the thin film is exposed to radiation at a dwell time of about 1 μs.

In certain embodiments, the method further comprises varying a pass (scan) number to obtain a desired dosage for each pattern.

In certain embodiments, the patterning is performed by shadow mask patterning with an electron energy of about 2 keV. In certain embodiments, the patterning is performed at an emission current between about 0.15 μA and about 4 μA, including about 0.15, 0.2, 0.3, 0.4, 0.5, 0.6, 0.7, 0.8, 0.9, 1.0, 1.5, 2.0, 2.5, 3.0, 3.5, and 4 μA. In certain embodiments, the patterning is performed for a duration ranging from about one minute to about one hour.

In some embodiments, the patterning resolution is improved by the use of a conductive underlayer.

### C. Dry Etching of Patterned Metal-Imidazolate Thin Films

In yet another embodiment, a method for the dry etching of patterned films is described, wherein the method comprises loading thin films, wherein the films are directly deposited by molecular layer deposition and comprise a zinc-imidazolate based film, into a reactor after irradiation and exposing them to a gaseous β-diketonate to form a zinc-imidazolate pattern in only the irradiated areas.

More particularly, in some embodiments, the presently disclosed subject matter provide a method for etching a thin film on a substrate, wherein the thin film comprises a thin film as described hereinabove, the method comprising reacting the thin film with a volatile reagent to produce a volatile organometallic product and an organic product described by the formula A+B=>C+D where A represents the metal/ligand containing film, B represents an volatile molecular etchant, C represents a volatile coordination complex of the etchant and metal, and D represents the volatile ligand originally contained in the film.

In certain embodiments, the etchant B comprises one or more β-diketonates. In particular embodiments, the one or more β-diketonates is selected from:

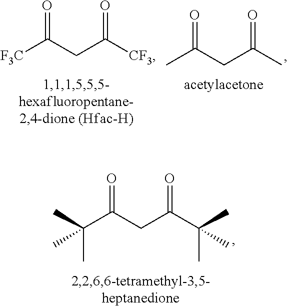

combinations thereof.

In some embodiments, the etchant species includes, but is not limited to, hexafluoroacetylacetone (Hfac-H). In some embodiments, the etchant species includes, but is not limited to, acetylacetonate.

In certain embodiments, the etchant is selected from oxygen-containing plasma, halogen-containing plasma, nitrogen-containing plasma, NOx, HCl, and combinations thereof.

In certain embodiments, the etchant is selected from oxygen-containing plasma, halogen-containing plasma, nitrogen-containing plasma, NOx, HCl, and combinations thereof.

In certain embodiments, the thin film is exposed to the etchant for a period of time between about 1 minute and about 60 minutes. In particular embodiments, the thin film is sequentially exposed to the etchant for a period of time between about 1 minute and about 15 minutes followed by purging with an inert gas comprising a combination of one or more of helium, neon, argon, krypton, nitrogen, or xenon, for a period of time between about 1 minute and about 15 minutes.

In certain embodiments, the method comprises heating the thin film to a temperature having a range between about 25° C. to about 400° C., including about 25, 30, 40, 50, 60, 70, 80, 90,100,150, 200, 250, 300, 350, and 400° C., in some embodiments, within a range of about 100° C. to about 200° C. including about 100, 105, 110, 115, 120, 125, 130, 135, 140, 145, 150, 155, 160, 165, 170, 175, 180, 185, 190, 195, and 200° C.

In certain embodiments, the method further comprises combining the etchant with an inert gas or plasma, an oxidizing gas or plasma, a halogen-containing gas or plasma, and combinations thereof. In particular embodiments, the inert gas or plasma is selected from helium, neon, argon, krypton, nitrogen, xenon, and combinations thereof.

In certain embodiments, the method comprises contacting the etchant, oxidizing gas or plasma, halogen-containing gas or plasma, inert gas, or combinations thereof, with the thin film within a temperature range of between about 25° C. to about 400° C. In certain embodiments, the method comprises contacting the etchant, oxidizing gas or plasma, halogen-containing gas or plasma, inert gas, or combinations thereof, with the thin film for an exposure time having a range between about 1 minute to about 120 minutes, including about 1, 2, 3, 4, 5, 6, 7, 8, 9, 10, 11, 12, 13, 14, 15, 16, 17, 18, 19, 20, 25, 30, 35, 40, 45, 50, 55, 60, 65, 70, 75, 80, 90,100,105, 110, 115, and 120 minutes, in some embodiments, within a range of about 2 minutes to about 60 minutes, including about 2, 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, 50, 51, 52, 53, 54, 55, 56, 57, 58, 59, and 60 min.

In certain embodiments, the method comprises contacting the etchant, oxidizing gas or plasma, halogen-containing gas or plasma, inert gas, or combinations thereof, with the thin film at a pressure of about 10×10⁻³ mbar or less. In certain embodiments, the method comprises contacting the etchant, oxidizing gas or plasma, halogen-containing gas or plasma, inert gas, or combinations thereof, with the thin film at an etchant partial pressure of about 1 mbar to about 100 mbar, including about 1, 2, 3, 4, 5, 6, 7, 8, 9, 10, 15, 20, 25, 30, 35, 40, 45, 50, 55, 60, 65, 70, 75, 80, 90, 95, and 100 mbar, preferably within a range of about 5 mbar to about 50 mbar, including about 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49 and 50 mbar.

In some embodiments, the resulting metal-imidazolate film pattern has a roughness of less than about 10 nm, preferably less than about 1 nm.

In some embodiments, the resulting metal-imidazolate film pattern has feature thickness between about 2 nm and about 50 nm, including about 2, 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49 and 50, as demonstrated by AFM.

In some embodiments, the resulting metal-imidazolate film pattern has a spacing of about 20-30 nm or more as demonstrated by AFM. In some embodiments, the resulting metal-imidazole film pattern has a line thickness of less than about 80 nm or more as demonstrated by AFM.

In some embodiments, the resulting metal-imidazolate film pattern has a pitch of about 20 nanometers or more as demonstrated by AFM.

In some embodiments, the resulting metal-imidazole film pattern has a line thickness of less than about 5 nm as demonstrated by AFM.

In some embodiments of this method, patterned ZIF or MOF materials are etched in place of the patterned metal-imidazolate films. These materials may include, but are not limited to, MOF thin films, ZIF thin films, single crystalline ZIFs like ZIF-L or ZIF-8 analogs, halogenated ZIFs, or a combination thereof.

Advantageously, the resists described herein are practical for potential application as a dry extreme ultraviolet lithography (EUVL) resist technology. The amorphous metal-imidazolate films are smooth and homogeneous to enable effective high-resolution patterning.

### D. Thin Films

In some embodiments, the presently disclosed subject matter provides a non-crystalline thin film having a chemical formula of MLₙ, wherein M is a metal ion, L is a ligand, and n is a number of ligands. In certain embodiments, the metal ion is Zn⁺².

In particular embodiments, the ligand comprises an imidazolate. In certain embodiments, the imidazolate is a derivative of 1,3-diazacyclopenta-2,4-diene having a chemical C₃N₂HR₃, wherein the R groups are positioned at the 1, 4, and 5 positions of 1,3-diazacyclopenta-2,4-diene and are each independently selected from —H, —CH₃, —CH₂CH₃, —Cl, —Br, —I, —C₄H₄, and —CHO. In more particular embodiments, the imidazolate is selected from:

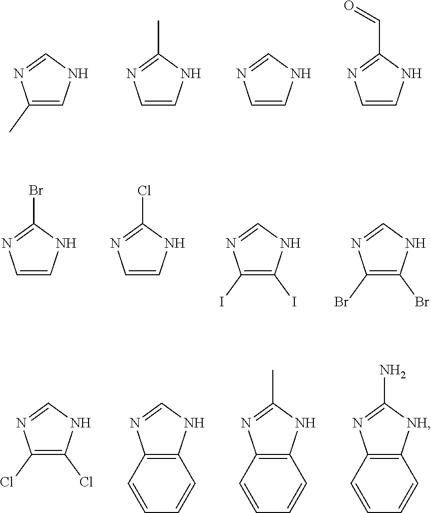

and combinations thereof.

In even yet more particular embodiments, the ligand comprises 2-methylimidazole (2 mIm). In certain embodiments, the thin film comprises a metal-imidazolate comprises a zinc-imidazolate.

In certain embodiments, the thin film has a line edge roughness of less than 1 nm, as evidenced by XRD. In certain embodiments, a pattern of the thin film has a feature resolution of about 5 nm. In certain embodiments, a pattern of the thin film has a roughness of less than about 10 nm. In certain embodiments, the thin film lacks a long-range order, as evidenced by XRD. In certain embodiments, the thin film has a thickness from about 2 nm to about 500 nm, including about 2, 5, 10, 20, 30, 40, 50, 60, 70, 80, 90,100, 200, 300, 400, and 500 nm. In certain embodiments, a pattern of the thin film has a feature thickness between about 2 and about 50 nm, including about 2, 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49 and 50 nm. In certain embodiments, a pattern of the thin film has a spacing of 400 nanometers or more. In certain embodiments, a pattern of the thin film has a line thickness of less than 80 nm. In certain embodiments, a pattern of the thin film has a pitch of 20 nanometers or more.

### E. Articles

In some embodiments, the presently disclosed subject matter provides an article comprising the presently disclosed non-crystalline thin film. In certain embodiments, the article is selected from an extreme ultraviolet lithography (EUVL) and electron-beam lithography (EBL) resist and a microelectronic device.

In other embodiments, the presently disclosed subject matter provides an article comprising the presently disclosed thin film, further comprising a material produced by irradiation of the thin film that is not removed by a subsequent etching process. In certain embodiments, the article is selected from a structural material, a dielectric barrier, and a photomask.

### F. Definitions

Unless otherwise defined, all technical and scientific terms used herein have the same meaning as commonly understood by one of ordinary skill in the art. In case of conflict, the present document, including definitions, will control. Preferred methods and materials are described below, although methods and materials similar or equivalent to those described herein can be used in practice or testing of the present disclosure. All publications, patent applications, patents, and other references mentioned herein are incorporated by reference in their entirety. The materials, methods, and examples disclosed herein are illustrative only and not intended to be limiting.

For purposes of this disclosure, the chemical elements are identified in accordance with the Periodic Table of the Elements, CAS version, Handbook of Chemistry and Physics, 75th Ed., inside cover, and specific functional groups are generally defined as described therein. Additionally, general principles of organic chemistry, as well as specific functional moieties and reactivity, are described in Sorrell, Organic Chemistry, 2nd edition, University Science Books, Sausalito, 2006; Smith, March's Advanced Organic Chemistry: Reactions, Mechanism, and Structure, 7th Edition, John Wiley & Sons, Inc., New York, 2013; Larock, Comprehensive Organic 6 Transformations, 3rd Edition, John Wiley & Sons, Inc., New York, 2018; and Carruthers, Some Modem Methods of Organic Synthesis, 3rd Edition, Cambridge University Press, Cambridge, 1987; the entire contents of each of which are incorporated herein by reference.

The term “imidazolate” is used herein to refer to the conjugate base of a five-membered imidazole ring having the chemical formula C₃N₂H₄ with substituents at the 1, 4, and 5 positions on the ring including, but not limited to, —H, —CH₃, —CH₂CH₃, —Cl, —Br, —I, —C₄H₄, or —CHO, and the like.

The term “metal-organic framework” or “MOF” is used herein to refer to crystalline materials consisting of metal clusters or ions coordinated to multivalent organic ligands, which are also referred to as linkers.

The term “zeolitic imidazolate framework” or “ZIF” is used herein to refer to a subset of MOFs that include metal atoms bound to imidazolate-type ligands.

As used herein, the term “amorphous” refers to a three-dimensional material lacking long range order.

As used herein, the term “metal-imidazolate,” refers to a class of compounds consisting of metal ions or clusters coordinated to imidazolate ligands. Organic ligands also are referred to as linkers.

The term “β-diketonate” or “acetylacetonate type compound” is used herein to refer to an organic compound having the chemical formula, —R(C═O)CH₂(C═O)R— wherein R is an organic substituent group including, but not limited to, CH₃ or CF₃, and the like.

As used herein, the term “ALD,” refers to atomic layer deposition, i.e., the process of depositing an inorganic thin film by sequential self-terminating reactions between a solid substrate and gaseous reactants.

As used herein, the term “MILD,” refers to molecular layer deposition, i.e., the process of depositing a thin film by sequential self-terminating reactions between a solid substrate and gaseous reactants, one or more of which is an organic molecule and the deposited groups from each half-cycle is a molecular fragment.

As used herein, the term “cycle” refers to the sequence of a single dose followed by a purge, either by inert carrier gas flow or dynamic vacuum, of each reagent used for an ALD or MLD process.

The term “half-cycle” is used herein to refer to a single dose followed by a purge, either by inert carrier gas flow or dynamic vacuum, of a single reagent in an ALD or MLD process.

The term “etching” is used herein to indicate the removal of solid material via the production of soluble or volatile species following exposure to liquid or vapor phase solvents or reagents.

As used herein, the term “dry” refers to a process that does not use liquid solvents.

As used herein, the term “lithography,” also referred to as “photolithography,” refers to the process of transferring a pattern to a photosensitive material on top of a wafer surface.

As used herein, the term “exposure,” also referred to as “irradiation,” refers to the process of bombardment of selected areas of a sample with an electron, X-ray, or EUV beam, or any other source that produces secondary electrons able to produce chemical modification within these areas.

The term “resist” is used herein to refer to a thin photosensitive layer used to transfer circuit patterns to the surface of a substrate on which the resist is deposited.

As used herein, the term “mask,” “photomask,” or “shadow mask” refers to a pre-patterned stencil that allows either light or electrons to pass through onto the resist only where the defined pattern is.

As used herein, the term “direct-write” or “direct-writing,” refers to patterning of a photoresist without the use of a mask, e.g., via a focused electron beam.

Following long-standing patent law convention, the terms “a,” “an,” and “the” include plural references, e.g., “one or more” when used in this application, including the claims, unless the context clearly dictates otherwise.

Throughout this specification and the claims, the terms “comprise,” “comprises,” and “comprising” are intended to be open-ended transitional phrases, terms, or words used in a non-exclusive sense that do not preclude the possibility of additional acts or structures, except where the context requires otherwise. Likewise, the terms “include,” “has,” “having,” “can,” and their grammatical variants are intended to be non-limiting, such that recitation of items in a list is not to the exclusion of other like items that can be substituted or added to the listed items.

The phrase “in one embodiment” or “in some embodiments” as used herein does not necessarily refer to the same embodiment, though it may. Furthermore, the phrase “in another embodiment” as used herein does not necessarily refer to a different embodiment, although it may. Thus, as described below, various embodiments of the invention may be readily combined, without departing from the scope or spirit of the invention.

For the purposes of this specification and appended claims, unless otherwise indicated, all numbers expressing amounts, sizes, dimensions, proportions, shapes, formulations, parameters, percentages, quantities, characteristics, and other numerical values used in the specification and claims, are to be understood as being modified in all instances by the term “about” even though the term “about” may not expressly appear with the value, amount or range. Accordingly, unless indicated to the contrary, the numerical parameters set forth in the following specification and attached claims are not and need not be exact, but may be approximate and/or larger or smaller as desired, reflecting tolerances, conversion factors, rounding off, measurement error and the like, and other factors known to those of skill in the art depending on the desired properties sought to be obtained by the presently disclosed subject matter. For example, the term “about,” when referring to a value can be meant to encompass variations of, in some embodiments, ±100% in some embodiments ±50%, in some embodiments ±20%, in some embodiments ±10%, in some embodiments ±5%, in some embodiments ±1%, in some embodiments ±0.5%, and in some embodiments ±0.1% from the specified amount, as such variations are appropriate to perform the disclosed methods or employ the disclosed compositions.

Further, the term “about” when used in connection with one or more numbers or numerical ranges, should be understood to refer to all such numbers, including all numbers in a range and modifies that range by extending the boundaries above and below the numerical values set forth. The recitation of numerical ranges by endpoints includes all numbers, e.g., whole integers, including fractions thereof, subsumed within that range (for example, the recitation of 1 to 5 includes 1, 2, 3, 4, and 5, as well as fractions thereof, e.g., 1.5, 2.25, 3.75, 4.1, and the like) and any range within that range.

### EXAMPLES

The following Examples have been included to provide guidance to one of ordinary skill in the art for practicing representative embodiments of the presently disclosed subject matter. In light of the present disclosure and the general level of skill in the art, those of skill can appreciate that the following Examples are intended to be exemplary only and that numerous changes, modifications, and alterations can be employed without departing from the scope of the presently disclosed subject matter. The synthetic descriptions and specific examples that follow are only intended for the purposes of illustration, and are not to be construed as limiting in any manner to make compounds of the disclosure by other methods.

### Example 1

### 1.1 Methods and Materials for Examples 1, 2, 3, and 4

Diethylzinc (DEZ) (95%, Strem Chemicals), 2-methylimidazole (2 mIm) (99%, Millipore-Sigma), imidazole-2-carboxaldehyde (Ica) (97%, ThermoFisher), hexafluoroacetylacetone (Hfac-H) (98.5%, Acros Organics), ethanol (99.5%, The Warner-Graham Company), and argon gas (>99.999%, AirGas) were used as received without further purification unless otherwise noted. Silicon (111) wafers were purchased from University Wafer, Inc. Silicon nitride supports (15- and 50-nm thick silicon nitride film on a 200-μm silicon frame with nine 0.1×0.1 mm viewing windows) for transmission electron microscopy (TEM) were purchased from Ted Pella.

X-ray diffraction (XRD) patterns were collected using a Rigaku MiniFlex powder X-ray diffractometer at 40 kV, 15 mA using a Cu Kα source (λ=1.5406 Å) in a 2-theta range of 5° to 400 at a step size of 0.01° and a scan rate of 1°/min.

Film thicknesses were measured using a Film Sense FS1 Ellipsometer using four LEDs with wavelengths between 465.27 nm and 641.13 nm. Native SiO₂ thickness was measured using the built-in SiO₂ on Si model, and deposited film thicknesses were measured with a Cauchy model.

SEM image acquisition was performed on a Tescan MIRA3 Scanning Electron Microscope operating at an acceleration voltage of 5 kV.

TEM image acquisition was performed on a Jeol F200 Transmission Electron Microscope operating at an acceleration voltage of 200 kV.

IR spectra were acquired on a PerkinElmer Spectrum One FTIR. Double side polished 300-μm thick Si substrates (University Wafer) coated with zinc-imidazolate films were used for collection of transmission spectra. Thickness-induced fringe effects were removed in MatLab version R2022b using the FourierDataProcessing toolbox by Victor Lorenz Fonfria.

XPS spectra were acquired on a PHI 5600 XPS with Mg Kα x-rays at a power of 300 W. Survey scans were acquired at a pass energy of 178.95 eV.

AFM images were collected on an Asylum MFP-3D with a NanoWorld NCHR Si tip with an image size of 512×512 pixels in tapping mode with a scan rate of approximately 0.5 Hz for large scans and 1 Hz for small area scans. Tip curvature is nominally less than 8 nm. The images were processed in Gwyddion, with line-scans taken by averaging over two adjacent scans.

Maskless direct write electron beam (E-beam) exposure experiments were performed on a Thermo Fisher Helios G4 UC Focused Ion Dual Beam microscope. Patterns were created in Adobe Photoshop using a pixel density of 454 pixels per inch and pixel size of 2.1 nm. Patterns were exported as BMP files and uploaded onto the Helios interface.

Maskless direct write electron beam (E-beam) exposure experiments were also performed at the University of Maryland's FabLab on a Raith e-line electron beam lithography system operating at an acceleration voltage of 30 kV with a 20-am aperture size and a current of 163.6 pA. Pattern files were generated and were exported as GDS files.

Shadow masked electron beam exposure experiments were performed with a Kimball Physics ELG-2A electron gun with EGPS-1022 power supply in a home-built ultra-high vacuum (UHV) chamber with base pressure of 5×10⁻⁹ torr. An exposure energy of 2 keV was used for patterning experiments. A rectangular aperture and a fine mesh shadow mask were used to selectively irradiate large sample areas, thereby generating numerous rectangular patterns with an average area of approximately 1200 μm². The electron dose was not measured directly, but instead was approximated by comparison with films patterned by direct write electron beam patterning in the Thermo Fisher Helios G4 UC Focused Ion Dual Beam Microscope.

### 1.2 MLD Growth of Metal-Imidazolate Films

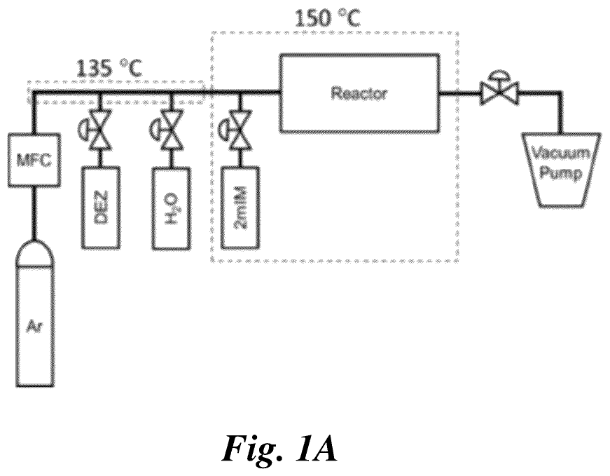

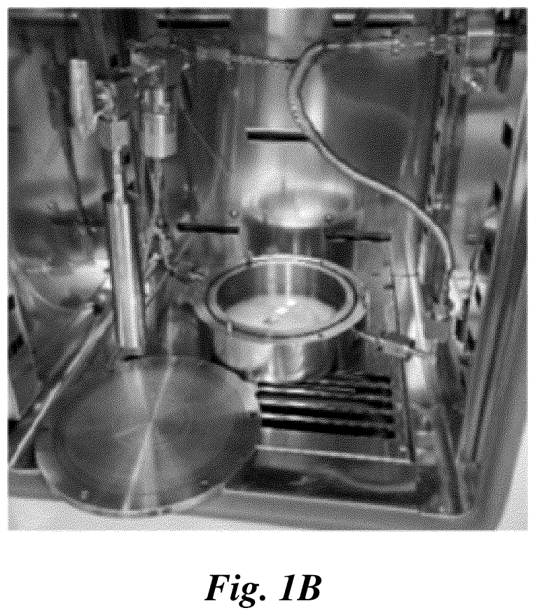

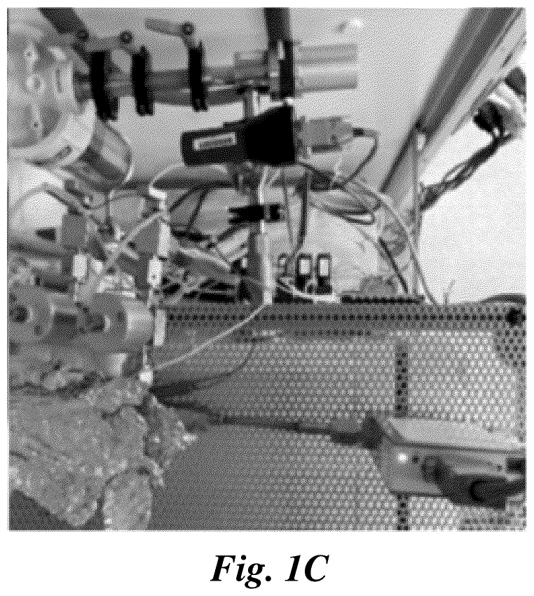

For MLD growth of metal-imidazolate films, precursors were pulsed sequentially into a home-built flow-through ALD reactor with purges of argon gas between subsequent pulses to remove byproducts and unreacted precursors. A schematic of the system is illustrated in FIG. 1. Silicon (111) wafers were cut into 1×1 cm² pieces and cleaned by sonication in ethanol for 15 s to be used as substrates. The native SiO₂ film thickness was measured by ellipsometry, and samples with a film thickness of greater than 2.1 nm were discarded due to contamination. For deposition of zinc-imidazolate films, the organometallic and organic precursors used were DEZ and 2 mIm, respectively. The DEZ precursor cylinder was maintained at ambient temperature, and the 2 mIm precursor cylinder was placed in a box oven with the reactor at 150° C., as shown in FIG. 1. Pulse lengths of DEZ and 2 mIm were fixed at 50 ms and 100 ms, respectively. Purge lengths were varied between about 15 s to about 100 s for both DEZ and 2 mIm. Argon flow in the reactor was set to 10 standard cubic centimeters per minute and the reactor pressure was between about 100 mTorr to about 1,000 mTorr during the deposition. Film thickness was determined by ellipsometry, and XRD patterns were collected to confirm the lack of long-range periodicity. AFM was used to confirm film smoothness and surface homogeneity.

### 1.3 Direct Write Patterning of Metal-Imidazolate Films

As-made direct deposited metal-imidazolate films were loaded into the Helios or Raith instrument. After focusing the image, the beam was paused over the selected location and pre-uploaded pattern images were overlaid in the view field. The desired areas were patterned at an acceleration voltage of 2, 5, 20, or 30 kV and a probe current of 100 or ˜ 165 pA. For the Helios instrument, all patterns were exposed at a dwell time of 1 s and the pass (scan) number was varied to obtain the desired dosage for each pattern. The electron dose was then determined by multiplying the current by the dwell time and the number of passes. For the Raith e-line instrument, dwell times were calculated for a desired dose in the Raith e-line software based on beam speed and current.

### 1.4 Shadow Mask Patterning of Metal-Imidazolate Films

As-made direct deposited metal-imidazolate films were placed in a custom sample holder, after which a 400-wire stainless steel mesh (hole size nominally 38 μm) was affixed to the holder, covering the sample. Samples were loaded into the UHV chamber via a load-lock port. After a chamber pressure of approximately 1×10⁻⁸ Torr was reached, a rectangular aperture approximately 1-mm wide and 6-mm long was moved between the electron gun and the sample. By orienting the long axis of the aperture orthogonal to the translation axis of the sample, multiple 1 mm×6 mm patterns could be made on a single 10-mm×10-mm sample. Patterning was performed with an electron energy of 2 kV and an emission current between 0.15 μA and 4 μA (beam current at target not measured) for durations ranging from one minute to one hour. The electron beam was blanked during movement between patterned areas by application of a 50V negative potential to the electron gun control grid. Some samples were exposed under these conditions without the use of masks to irradiate an entire sample wafer.

### 1.5 Dry Etching of Patterned Films

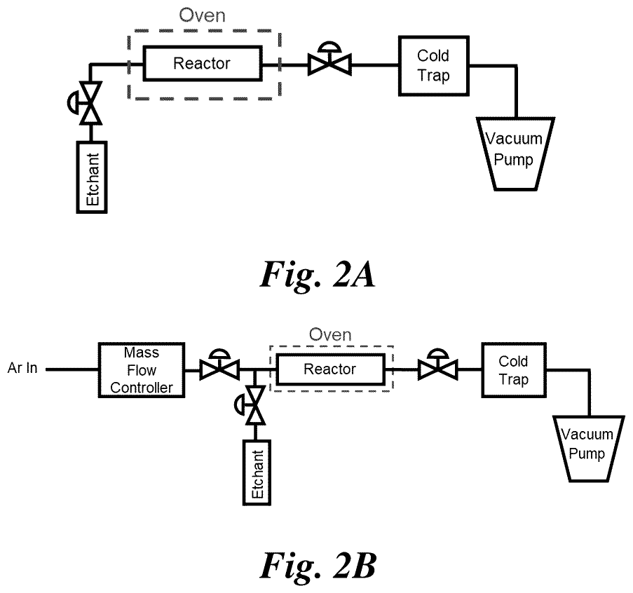

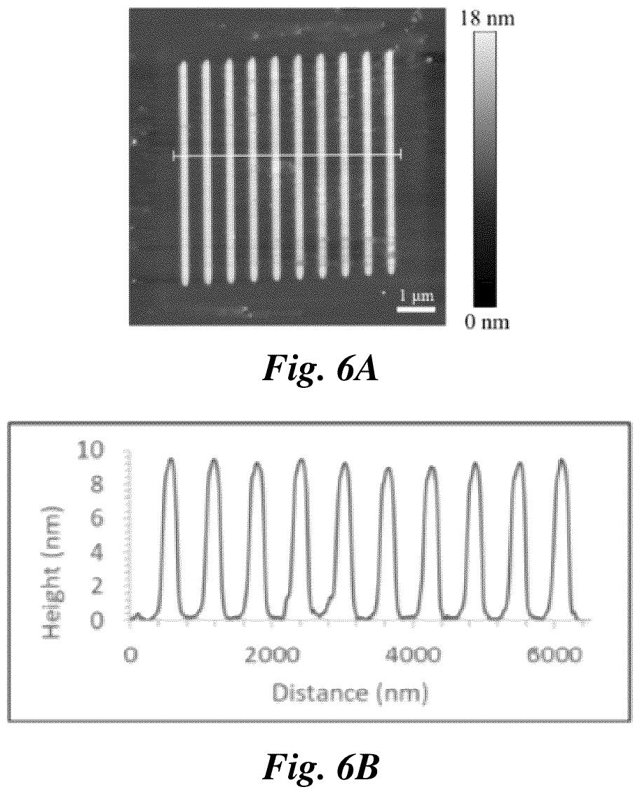

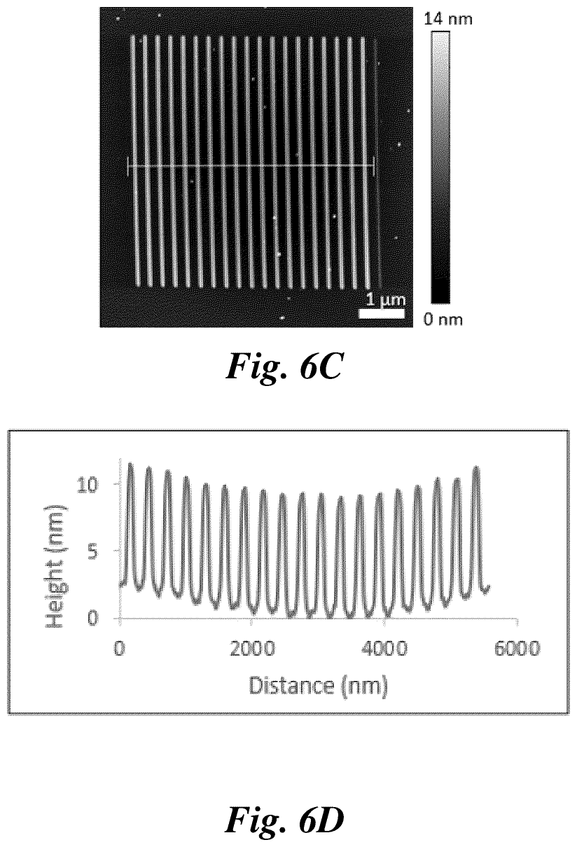

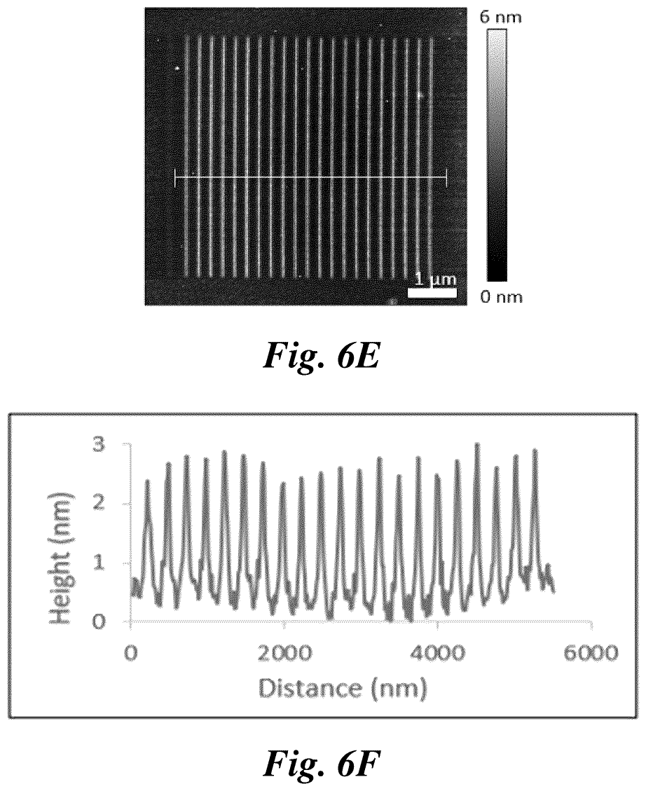

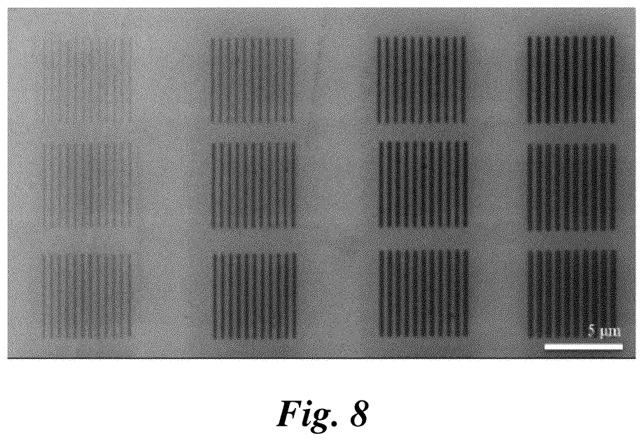

The exposed films were placed in a cylindrical quartz reactor system and transferred to an oven. A schematic of the system is illustrated in FIG. 2A. A vial containing <1 mL of Hfac-H was placed outside the oven and connected to the reactor inlet with a pneumatically-actuated diaphragm valve separating the reactor from the etchant. The reactor outlet was connected to a cold trap and vacuum pump with a second pneumatically-actuated diaphragm valve separating the reactor from the vacuum. The system was heated to 120° C. under dynamic vacuum and evacuated for 30 minutes until the system pressure had stabilized (approximately 0.025 mbar). For a single treatment cycle, the Hfac-H valve was opened for about is to 10 s and the sample was exposed to etchant vapors under static vacuum for between about 5 minutes to about 15 minutes before being purged by dynamic vacuum for between about 5 minutes to about 15 minutes. Samples were treated for between 1 to 10 treatment cycles. Following treatment, the system was evacuated under dynamic vacuum for 30 minutes to remove volatile species. The vacuum was then shut off and the system was allowed to cool to room temperature. After etching experiments, top-down SEM imaging (FIG. 8) and AFM height mapping (FIG. 6A) was performed to evaluate pattern dimensions and surface roughness.

### 1.6 Growth of ZIF-8 Thin Films

ZnmIm films of 60-nm thickness were grown in 400 cycles of DEZ and 2 mIm MLD at 150° C. The films were placed on a stainless steel mesh within a quartz tube with 100-mg 2 mIm that was evacuated under dynamic vacuum for 30 minutes at room temperature. The reactor vessel was then heated to 120° C. for two hours under static vacuum. The resulting films were activated at 120° C. for one hour under dynamic vacuum to remove condensed and adsorbed 2 mIm.

1.7 Pattern Transfer into Silicon Substrates

An Oxford ICP RIE PlasmaLab 100 Fluorine Etcher was used at the University of Maryland's FabLab. Preset Oxford recipes were used to test fluorine etching. The “Si Waveguide Etch” recipe uses the following specifications: 25 sccm SF₆, 50 sccm C₄F8, O₂ clean gas, 5-10 mTorr He, 20 W RF, 1200 W ICP, 20° C. The “Submicron Silicon Etch” recipe uses the following specifications: 12 sccm SF₆, 27 sccm C₄F8, O₂ clean gas, 10 mTorr He, 20 W RF, 750 W ICP, 20° C. The recipe default plasma exposure time is 60 seconds, but desired times between 1-60 seconds were tested.

### Example 2

### 2.1 MLD Growth of Metal-Imidazolate Films

For MLD growth of metal-imidazolate films, precursors were pulsed sequentially into a home-built flow-through ALD reactor with purges of argon gas between subsequent pulses to remove byproducts and unreacted precursors. A schematic of the system is illustrated in FIG. 1. Silicon (111) wafers were cut into 1×1 cm² pieces and cleaned by sonication in ethanol for 15 s to be used as substrates. The native SiO₂ film thickness was measured by ellipsometry, and samples with a film thickness of greater than 2.1 nm were discarded due to contamination. For deposition of zinc-imidazolate films, the organometallic and organic precursors used were DEZ and 2 mIm, respectively. The DEZ precursor cylinder was maintained at ambient temperature, and the 2 mIm precursor cylinder was placed in a box oven with the reactor at 150° C., as shown in FIG. 1. Pulse lengths of DEZ and 2 mIm were fixed at 50 ms and 100 ms, respectively. Purge lengths were varied between about 15 s to about 100 s for both DEZ and 2 mIm. Argon flow in the reactor was set to 10 standard cubic centimeters per minute and the reactor pressure was between about 500 mTorr to about 1,000 mTorr during the deposition. Film thickness was determined by ellipsometry, and XRD patterns were collected to confirm the lack of long-range periodicity. AFM was used to confirm film smoothness and surface homogeneity.

### 2.2 Direct Write Patterning of Metal-Imidazolate Films

As-made direct deposited metal-imidazolate films were loaded into the Helios instrument. After focusing the image, the beam was paused over the selected location and pre-uploaded pattern images were overlaid in the view field. The desired areas were patterned at an acceleration voltage of 2, 5, or 20 kV and a probe current of 100 pA. All patterns were exposed at a dwell time of 1 s. The pass (scan) number was varied to obtain the desired dosage for each pattern. The electron dose was determined by multiplying the current by the dwell time and the number of passes.

### 2.3 Shadow Mask Patterning of Metal-Imidazolate Films

As-made direct deposited metal-imidazolate films were placed in a custom sample holder, after which a 400-wire stainless steel mesh (hole size nominally 38 μm) was affixed to the holder, covering the sample. Samples were loaded into the UHV chamber via a load-lock port. After a chamber pressure of approximately 1×10⁻⁸ Torr was reached, a rectangular aperture approximately 1-mm wide and 6-mm long was moved between the electron gun and the sample. By orienting the long axis of the aperture orthogonal to the translation axis of the sample, multiple 1 mm×6 mm could be made on a single 10-mm×10-mm sample. Patterning was performed with an electron energy of 2 kV and an emission current between 0.15 μA and 4 μA (beam current at target not measured) for durations ranging from one minute to one hour. The electron beam was blanked during movement between patterned areas by application of a 50V negative potential to the electron gun control grid. Some samples were exposed under these conditions without the use of masks to irradiate an entire sample wafer.

2.4 Dry Etching of Patterned Films with Argon Flow

The exposed films were placed in a cylindrical quartz reactor system and transferred to an oven. A schematic of the system is illustrated in FIG. 2B. Outside of the oven, pneumatically-actuated diaphragm valves were used to separately connect a mass flow controller for argon and a vial containing >1 mL of Hfac-H to the reactor. The reactor outlet was connected to a cold trap and vacuum pump with a third pneumatically-actuated diaphragm valve separating the reactor from the vacuum. The system was heated to 120° C. under dynamic vacuum with an imposed argon flow of 5 sccm and evacuated for 30 minutes until the system pressure had stabilized (approximately 0.025 mbar). For a single treatment cycle, the Hfac-H valve was opened for about is to about 10 s and the sample was exposed to etchant vapors under static vacuum without argon flow for between about 5 minutes to about 15 minutes before being purged by dynamic vacuum with argon flow for between about 5 minutes to about 15 minutes followed by dynamic vacuum without argon flow for 1 minute. Samples were treated for between 1 to 10 treatment cycles. Following treatment, the system was evacuated under dynamic vacuum with argon flow for 30 minutes to remove volatile species. The vacuum and argon flow were then shut off and the system was allowed to cool to room temperature. After etching experiments, top-down SEM imaging and AFM height mapping (FIG. 6C) was performed to evaluate pattern dimensions and surface roughness.

### Example 3

### 3.1 MLD Growth of Metal-Imidazolate Films on Silicon Nitride TEM Supports

For MLD growth of metal-imidazolate films, precursors were pulsed sequentially into a home-built flow-through ALD reactor with purges of argon gas between subsequent pulses to remove byproducts and unreacted precursors. A schematic of the system is illustrated in FIG. 1. Silicon nitride (SiN) TEM supports were treated in an O₂ plasma cleaner for 5 minutes and used as substrates. For deposition of zinc-imidazolate films, the organometallic and organic precursors used were DEZ and 2 mIm, respectively. The DEZ precursor cylinder was maintained at ambient temperature, and the 2 mIm precursor cylinder was placed in a box oven with the reactor at 150° C., as shown in FIG. 1. Pulse lengths of DEZ and 2 mIm were fixed at 50 ms and 100 ms, respectively. Purge lengths were varied between about 15 s to about 100 s for both DEZ and 2 mIm. Argon flow in the reactor was set to 10 standard cubic centimeters per minute and the reactor pressure was between about 500 mTorr to about 1,000 mTorr during the deposition. Film thickness was determined by ellipsometry, and XRD patterns were collected to confirm the lack of long-range periodicity. AFM was used to confirm film smoothness and surface homogeneity.

### 3.2 Direct Write Patterning of Metal-Imidazolate Films on Silicon Nitride TEM Supports

As-made direct deposited metal-imidazolate films were loaded into the Helios instrument. After focusing the image, the beam was paused over the selected location and pre-uploaded pattern images were overlaid in the view field. The desired areas were patterned at an acceleration voltage of 2, 5, or 20 kV and a probe current of 100 pA. All patterns were exposed at a dwell time of 1 μs. The pass (scan) number was varied to obtain the desired dosage for each pattern. The electron dose was determined by multiplying the current by the dwell time and the number of passes.

3.3 Dry Etching of Patterned Films with Argon Flow on Silicon Nitride TEM Supports

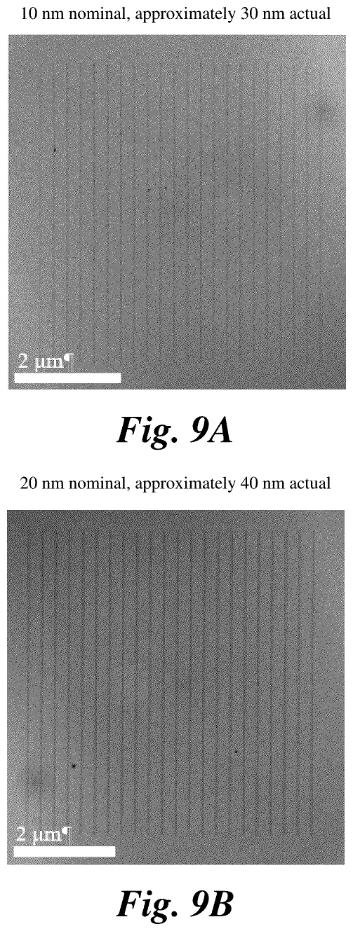

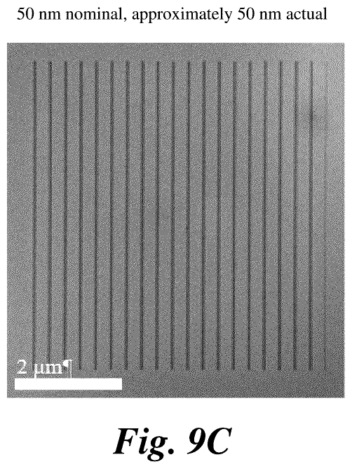

The exposed films were placed in a cylindrical quartz reactor system and transferred to an oven. A schematic of the system is illustrated in FIG. 2B. Outside of the oven, pneumatically-actuated diaphragm valves were used to separately connect a mass flow controller for argon and a vial containing >1 mL of Hfac-H to the reactor. The reactor outlet was connected to a cold trap and vacuum pump with a third pneumatically-actuated diaphragm valve separating the reactor from the vacuum. The system was heated to 120° C. under dynamic vacuum with an imposed argon flow of 5 sccm and evacuated for 30 minutes until the system pressure had stabilized (approximately 0.025 mbar). For a single treatment cycle, the Hfac-H valve was opened for between about is to about 10 s and the sample was exposed to etchant vapors under static vacuum without argon flow for between about 5 minutes to about 15 minutes before being purged by dynamic vacuum with argon flow for 5-15 minutes followed by dynamic vacuum without argon flow for 1 minute. Samples were treated for between 1 to 10 treatment cycles. Following treatment, the system was evacuated under dynamic vacuum with argon flow for 30 minutes to remove volatile species. The vacuum and argon flow were then shut off and the system was allowed to cool to room temperature. After etching experiments, TEM imaging (FIG. 9) and AFM height mapping was performed to evaluate pattern dimensions and surface roughness.

### Example 4

### 4.1 MLD Growth of Metal-Imidazolate Films

For MLD growth of metal-imidazolate films, precursors were pulsed sequentially into a home-built flow-through ALD reactor with purges of argon gas between subsequent pulses to remove byproducts and unreacted precursors. A schematic of the system is illustrated in FIG. 1. Silicon (111) wafers were cut into 1×1 cm² pieces and cleaned by sonication in ethanol for 15 s to be used as substrates. The native SiO₂ film thickness was measured by ellipsometry, and samples with a film thickness of greater than 2.1 nm were discarded due to contamination. For deposition of zinc-imidazolate films, the organometallic and organic precursors used were DEZ and Ica, respectively. The DEZ precursor cylinder was maintained at ambient temperature, and the Ica precursor cylinder was placed in a box oven with the reactor at 150° C., as shown in FIG. 1. Pulse lengths of DEZ and Ica were fixed at 50 ms and 1 s, respectively. Purge lengths were varied between about 15 s to about 100 s for both DEZ and Ica. Argon flow in the reactor was set to 10 standard cubic centimeters per minute and the reactor pressure was between about 500 mTorr to about 1,000 mTorr during the deposition. Film thickness was determined by ellipsometry, and XRD patterns were collected to confirm the lack of long-range periodicity. AFM was used to confirm film smoothness and surface homogeneity.

### 4.2 Direct Write Patterning of Metal-Imidazolate Films

As-made direct deposited metal-imidazolate films were loaded into the Helios instrument. After focusing the image, the beam was paused over the selected location and pre-uploaded pattern images were overlaid in the view field. The desired areas were patterned at an acceleration voltage of 2, 5, or 20 kV and a probe current of 100 pA. All patterns were exposed at a dwell time of 1 μs. The pass (scan) number was varied to obtain the desired dosage for each pattern. The electron dose was determined by multiplying the current by the dwell time and the number of passes.

### 4.3 Shadow Mask Patterning of Metal-Imidazolate Films

As-made direct deposited metal-imidazolate films were placed in a custom sample holder, after which a 400-wire stainless steel mesh (hole size nominally 38 μm) was affixed to the holder, covering the sample. Samples were loaded into the UHV chamber via a load-lock port. After a chamber pressure of approximately 1×10⁸ Torr was reached, a rectangular aperture approximately 1-mm wide and 6-mm long was moved between the electron gun and the sample. By orienting the long axis of the aperture orthogonal to the translation axis of the sample, multiple 1 mm×6 mm patterns could be made on a single 10-mm×10-mm sample. Patterning was performed with an electron energy of 2 kV and an emission current between 0.15 μA and 4 μA (beam current at target not measured) for durations ranging from one minute to one hour. The electron beam was blanked during movement between patterned areas by application of a 50V negative potential to the electron gun control grid. Some samples were exposed under these conditions without the use of masks to irradiate an entire sample wafer.

4.4 Dry Etching of Patterned Films with Argon Flow

The exposed films were placed in a cylindrical quartz reactor system and transferred to an oven. A schematic of the system is illustrated in FIG. 2B. Outside of the oven, pneumatically-actuated diaphragm valves were used to separately connect a mass flow controller for argon and a vial containing >1 mL of Hfac-H to the reactor. The reactor outlet was connected to a cold trap and vacuum pump with a third pneumatically-actuated diaphragm valve separating the reactor from the vacuum. The system was heated to 120° C. under dynamic vacuum with an imposed argon flow of 5 sccm and evacuated for 30 minutes until the system pressure had stabilized (approximately 0.025 mbar). For a single treatment cycle, the Hfac-H valve was opened for between about is to about 10 s and the sample was exposed to etchant vapors under static vacuum without argon flow for between about 5 minutes to about 15 minutes before being purged by dynamic vacuum with argon flow for 5-15 minutes followed by dynamic vacuum without argon flow for 1 minute. Samples were treated for between 1 to 10 treatment cycles. Following treatment, the system was evacuated under dynamic vacuum with argon flow for 30 minutes to remove volatile species. The vacuum and argon flow were then shut off and the system was allowed to cool to room temperature.

### Example 5

### 5.1 MLD Growth of Metal-Imidazolate Films

For MLD growth of metal-imidazolate films, precursors were pulsed sequentially into a home-built flow-through ALD reactor with purges of argon gas between subsequent pulses to remove byproducts and unreacted precursors. A schematic of the system is illustrated in FIG. 1. Silicon (111) wafers were cut into 1×1 cm² pieces and cleaned by sonication in ethanol for 15 s to be used as substrates. The native SiO₂ film thickness was measured by ellipsometry, and samples with a film thickness of greater than 2.1 nm were discarded due to contamination. For deposition of zinc-imidazolate films, the organometallic and organic precursors used were DEZ and 2 mIm, respectively. The DEZ precursor cylinder was maintained at ambient temperature, and the 2 mIm precursor cylinder was placed in a box oven with the reactor at 150° C., as shown in FIG. 1. Pulse lengths of DEZ and 2 mIm were fixed at 50 ms and 100 ms, respectively. Purge lengths were set to 30 s for DEZ and 45 s for 2 mIm. Argon flow in the reactor was set to 10 standard cubic centimeters per minute and the reactor pressure was between about 500 mTorr to about 1,000 mTorr during the deposition. Film thickness was determined by ellipsometry, and XRD patterns were collected to confirm the lack of long-range periodicity. AFM was used to confirm film smoothness and surface homogeneity.

### 5.2 High Resolution Direct Write Patterning of Metal-Imidazolate Films

As-made direct deposited metal-imidazolate films were loaded into the Raith e-line instrument. After focusing and field alignment, the beam was centered over the selected location and pre-uploaded pattern images were overlaid in the view field. The desired areas were patterned at an acceleration voltage of 30 kV with a 20-am aperture size and a current of 163.6 pA. Pattern dwell times were calculated for a desired dose in the Raith e-line software based on beam speed and current.

5.3 Dry Etching of Patterned Films with Argon Flow

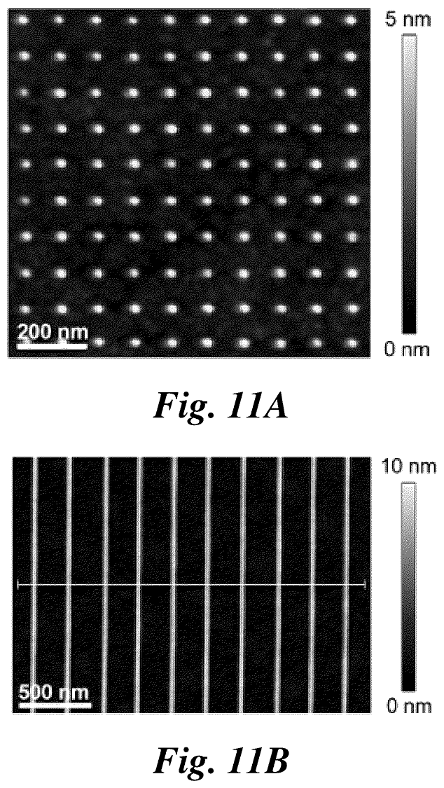

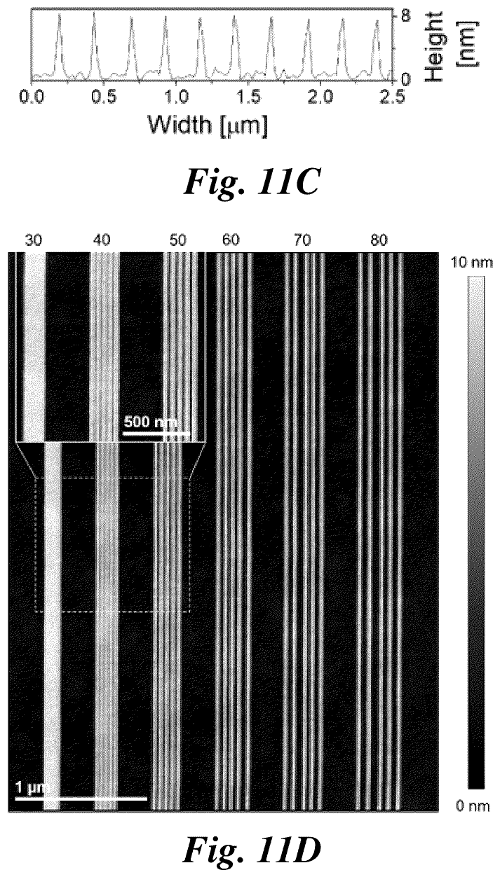

The exposed films were placed in a cylindrical quartz reactor system and transferred to an oven. A schematic of the system is illustrated in FIG. 2B. Outside of the oven, pneumatically-actuated diaphragm valves were used to separately connect a mass flow controller for argon and a precursor cylinder of Hfac-H to the reactor. The reactor outlet was connected to a cold trap and vacuum pump with a third pneumatically-actuated diaphragm valve separating the reactor from the vacuum. The system was heated to 120° C. under dynamic vacuum with an imposed argon flow of 5 sccm and evacuated for 30 minutes until the system pressure had stabilized (approximately 0.025 mbar). For a single treatment cycle, the Hfac-H valve was opened for about is to about 10 s and the sample was exposed to etchant vapors under static vacuum without argon flow for between about 5 minutes to about 15 minutes before being purged by dynamic vacuum with argon flow for between about 5 minutes to about 15 minutes followed by dynamic vacuum without argon flow for 1 minute. Samples were treated for between 1 to 10 treatment cycles. Following treatment, the system was evacuated under dynamic vacuum with argon flow for 30 minutes to remove volatile species. The vacuum and argon flow were then shut off and the system was allowed to cool to room temperature. After etching experiments, AFM height mapping (FIG. 11) was performed to evaluate pattern dimensions and surface roughness.

### Example 6

### 6.1 MLD Growth of Metal-Imidazolate Films on Silicon Nitride TEM Supports

For MLD growth of metal-imidazolate films, precursors were pulsed sequentially into a home-built flow-through ALD reactor with purges of argon gas between subsequent pulses to remove byproducts and unreacted precursors. A schematic of the system is illustrated in FIG. 1. Silicon nitride (SiN) TEM supports were treated in an O₂ plasma cleaner for 5 minutes and used as substrates. For deposition of zinc-imidazolate films, the organometallic and organic precursors used were DEZ and 2 mIm, respectively. The DEZ precursor cylinder was maintained at ambient temperature, and the 2 mIm precursor cylinder was placed in a box oven with the reactor at 150° C., as shown in FIG. 1. Pulse lengths of DEZ and 2 mIm were fixed at 50 ms and 100 ms, respectively. Purge lengths were set to 30 s for DEZ and 45 s for 2 mIm. Argon flow in the reactor was set to 10 standard cubic centimeters per minute or a space time of 0.1-2 s, including about 0.1, 0.11, 0.12, 0.13, 0.14, 0.15, 0.16, 0.17, 0.18, 0.19, 0.2, 0.3, 0.4, 0.5, 0.6, 0.7, 0.8, 0.9, 1.0, 1.1, 1.2, 1.3, 1.4, 1.5, 1.6, 1.7, 1.8, 1.9, and 2.0 s, and the reactor pressure was between about 100 mTorr to about 1,000 mTorr during the deposition.

### 6.2 High Resolution Direct Write Patterning of Metal-Imidazolate Films on Silicon Nitride TEM Supports

As-made direct deposited metal-imidazolate films were loaded into the Helios instrument. After focusing the image, the beam was paused over the selected location and pre-uploaded pattern images were overlaid in the view field. The desired areas were patterned at an acceleration voltage of 20 or 30 kV and a probe current of 100 pA. All patterns were exposed at a dwell time of 1 s. The pass (scan) number was varied to obtain the desired dosage for each pattern. The electron dose was determined by multiplying the current by the dwell time and the number of passes.

6.3 Dry Etching of Patterned Films with Argon Flow on Silicon Nitride TEM Supports

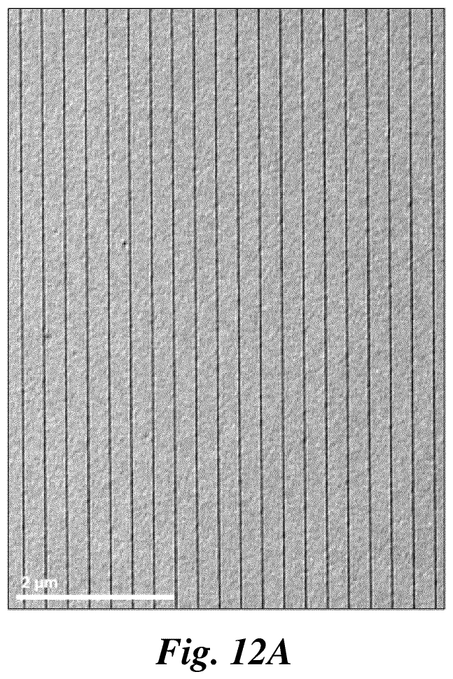

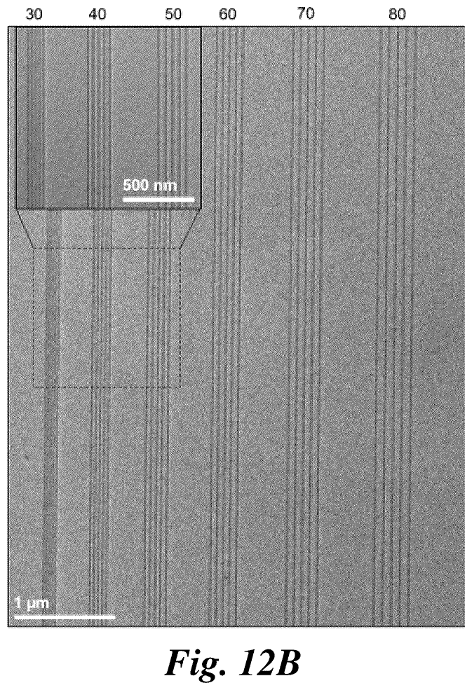

The exposed films were placed in a cylindrical quartz reactor system and transferred to an oven. A schematic of the system is illustrated in FIG. 2B. Outside of the oven, pneumatically-actuated diaphragm valves were used to separately connect a mass flow controller for argon and a precursor cylinder of Hfac-H to the reactor. The reactor outlet was connected to a cold trap and vacuum pump with a third pneumatically-actuated diaphragm valve separating the reactor from the vacuum. The system was heated to 120° C. under dynamic vacuum with an imposed argon flow of 5 sccm and evacuated for 30 minutes until the system pressure had stabilized (approximately 0.025 mbar). For a single treatment cycle, the Hfac-H valve was opened for between about is to about 10 s and the sample was exposed to etchant vapors under static vacuum without argon flow for between about 5 minutes to about 15 minutes before being purged by dynamic vacuum with argon flow for 5-15 minutes followed by dynamic vacuum without argon flow for 1 minute. Samples were treated for between 1 to 10 treatment cycles. Following treatment, the system was evacuated under dynamic vacuum with argon flow for 30 minutes to remove volatile species. The vacuum and argon flow were then shut off and the system was allowed to cool to room temperature. After etching experiments, TEM imaging (FIG. 12) was performed to evaluate pattern dimensions and surface roughness.

### Example 7

7.1 Pattern Transfer into Silicon Wafers using Fluorine Plasma Etching

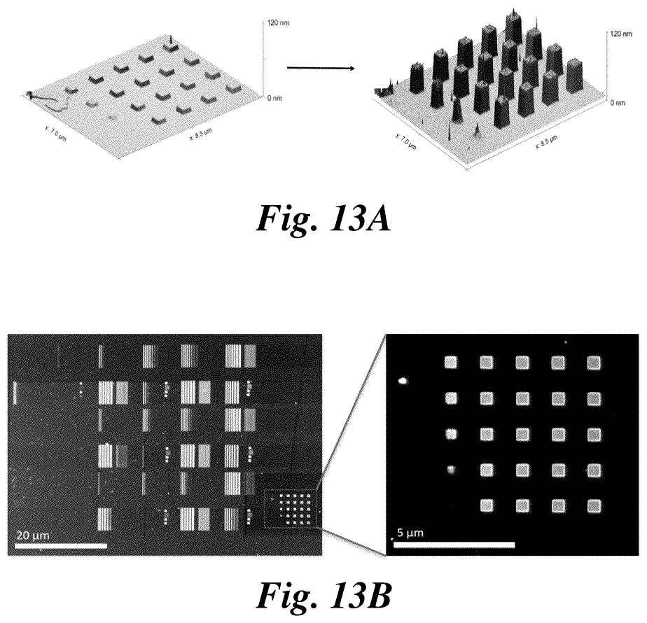

After the process flow outlined in EXAMPLE 5, samples patterned on Si wafers were loaded into the Oxford Fluorine Plasma Etcher. Preset Oxford recipes were used to test fluorine etching. Baseline experiments were conducted using a preset Oxford pseudo-Bosch “Si Waveguide Etch” recipe using SF₆ and C₄F₈ plasmas. Initial measurements revealed significant surface roughening. Subsequently, a different Oxford recipe, “Submicron Si Etch”, with a slower silicon etch rate was employed with the aim of enhancing etch selectivity and reducing surface roughness. The recipe default plasma exposure time is 60 seconds, but desired times between 1-60 seconds were tested. After etching experiments, AFM height mapping (FIG. 13A) and SEM imaging (FIG. 13B) were performed to evaluate pattern transfer and surface roughness.

### Example 8

### Analysis for Examples 1-7

### 8.1 Ellipsometry

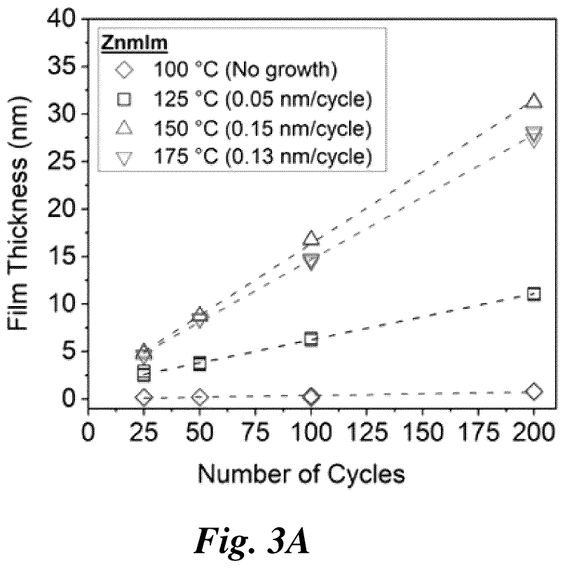

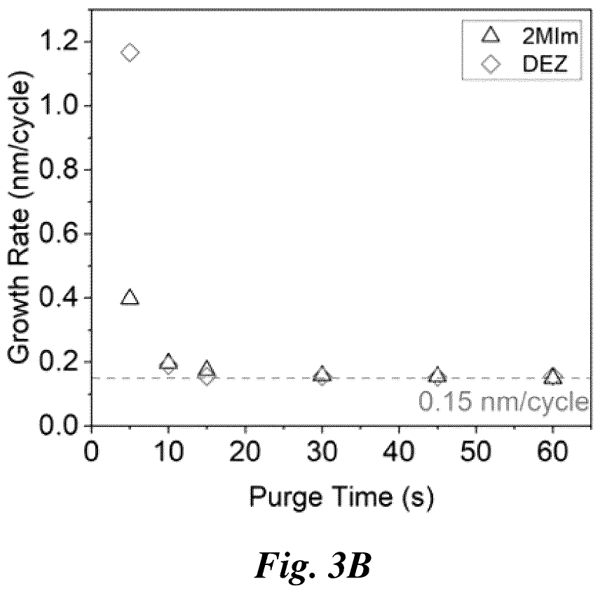

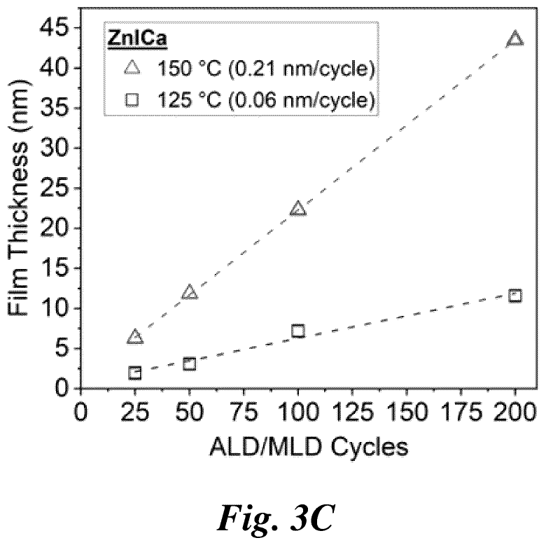

Film thicknesses were measured using a Film Sense FSI ellipsometer. The amplitude of the reading was maximized by adjusting the x- and y-stage controls. As shown in FIG. 3A, film thickness measurements are linearly related to the number of cycles as expected for ALD/MLD-type growth. As shown in FIG. 3B, CVD-type growth is observed at shorter argon purge times due to insufficient precursor purging, while the growth rate is not dependent on the purge time at longer purge times.

### 8.2 XRD

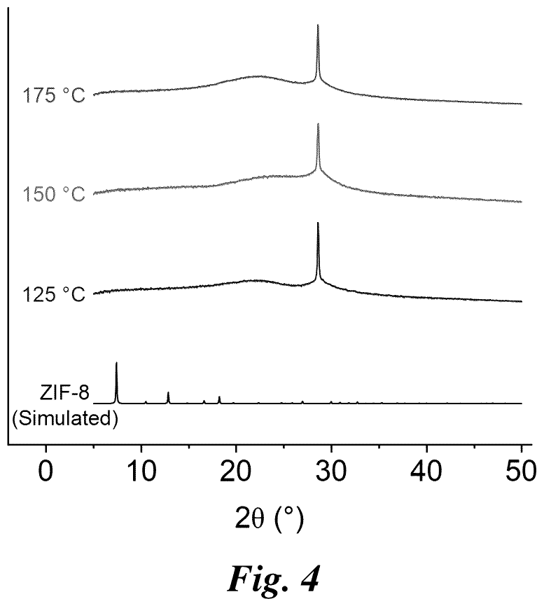

X-ray diffraction (XRD) patterns were collected using a Rigaku MiniFlex powder X-ray diffractometer at 40 kV, 15 mA using a Cu Kα source (λ=1.5406 Å) in a 20 range of 5 to 400 at a step size of 0.010 and a scan rate of 1°/min. Samples were placed on a low-background glass sample holder in the diffractometer. As shown in FIG. 4, the XRD patterns of the ALD/MLD zinc-imidazolate films do not have any peaks, in contrast to the ALD ZnO films or ZIF-8 films formed by vapor phase conversion of ZnO to ZIF-8 prepared in a method previously described (Stassen et al., 2016). The Si(111) substrate peak is visible at a 2θ value of approximately 28.5°.

### 8.3 AFM

AFM images were collected on an Asylum MFP-3D with a NanoWorld NCHR Si tip with an image size of 512×512 pixels in tapping mode with a scan rate of approximately 0.5 Hz for large scans and 1 Hz for small area scans. Tip curvature is nominally less than 8 nm. The images were processed in Gwyddion, with line-scans taken by averaging over two adjacent scans.

### 8.4 IR

IR spectra were acquired on a Nicolet iS5 FTIR spectrometer. Double side polished 300-μm thick Si substrates (University Wafer) coated with zinc-imidazolate films were used for collection of transmission spectra. Spectra were collected at 64 scans with a resolution of 2 cm⁻¹. Thickness induced fringe effects were removed in MatLab version R2022b using the FourierDataProcessing toolbox by Victor Lorenz Fonfria. A Fourier apodization utilizing Blackman functions served to remove the periodic interference from the spectra. Following this correction, the Si substrate spectrum was subtracted from the zinc-imidazolate film spectrum.

### 8.5 XPS

XPS spectra were acquired on a PHI 5600 XPS with Mg Kα x-rays at a power of 300 W. Survey scans were acquired at a pass energy of 178.95 eV.

### 8.6 SEM

SEM image acquisition was performed on a Tescan MIRA3 Scanning Electron Microscope operating at an acceleration voltage of 5 kV. The images were processed in Gwyddion to increase image brightness and contrast.

### 8.7 TEM

TEM image acquisition was performed on a Jeol F200 Transmission Electron Microscope operating at an acceleration voltage of 200 kV. The images were processed in Gwyddion to increase image brightness and contrast.

### Example 9

### 9.1 Results and Discussion

Photolithography is one of the main techniques used by the semiconductor industry to fabricate optoelectronic devices. This process involves the use of a thin photosensitive layer, called a resist, to transfer circuit patterns to the surface of a semiconductor substrate. The development of single-nanometer pattern features in the last decade has been achieved largely in part due to the use of shorter wavelength imaging radiation called extreme ultraviolet lithography (EUVL) (13.5-nm wavelength light source, energy of 92 eV). EUV systems can reduce critical feature dimensions while maintaining high resolution, pattern fidelity, and low line edge roughness (LER) but do suffer from limited power, high cost, and lack of resist materials that have high sensitivity at a wavelength of 13.5 nm (Saifullah et al., 2022). In EUVL, the resist sensitivity reflects both the absorptivity of EUV photons and the susceptibility to chemical changes induced by low energy electrons, which will be exploited during the development step, upon exposure to EUV irradiation.

To accommodate the demands of 248- and 193-nm lithography, chemically amplified resists (CARs) were used and effectively achieved high resolution and LER. With the progression toward 13.5-nm lithography, CARs, which are primarily organic based, suffer from compositional inhomogeneity in addition to low EUV sensitivity and resolution (Hasan et al., 2018). With strategies such as improving acid generation efficiency and incorporating per-fluorinated photo-acid generators (PAGs), CARs can currently achieve industry demands, but at high processing costs. Additionally, the use of additives to improve resist properties can lead to contamination issues. Furthermore, a commonly employed post exposure bake used in resist processing causes PAGs to diffuse in the resist, further blurring patterned features (Levinson, 2020). Polymer resists in general suffer from an inherently high line edge roughness because a diameter of several nanometers for high molecular weight polymers employed in resists represents a significant fraction of nanometer scale patterns (Yamaguchi et al., 1999). Due to their cost and limitations, CARs are not expected to keep up with the progressing semiconductor industry (Saifullah et al., 2022).

In recent years, there has been a shift toward using alternative resist materials, specifically toward metal-containing resists that have higher EUV absorption cross sections than traditional polymer-based resists (Fallica et al., 2018). Because they have increased EUV absorbance, incorporating metals into resist technologies will improve durability, and more importantly sensitivity, which permits shorter exposures thereby reducing undesired exposure resulting from stochastic effects like photon shot noise inherent to weak EUV light sources.

Metal-imidazolate films have shown particular promise for use as resists. Compared to traditional polymer-based resists consisting primarily of carbon, hydrogen, oxygen, and nitrogen, metal-imidazolate films are more sensitive to EUV and e-beam irradiation due to the higher EUV optical density of transition metals (Li et al., 2017; Manouras et al., 2020). One class of well-established metal-imidazolate films are zeolitic imidazolate frameworks (ZIFs), which are a particularly chemically and thermally stable type of metal-organic framework (MOF). The use of this class of materials is beneficial as hybrid organic-inorganic thin films can be readily deposited via vapor phase techniques which will greatly increase film uniformity compared to polymer-based resists in addition to increased process throughput and industrial scalability (Sundberg et al., 2014). Model ZIFs like zinc-based ZIF-8 can be deposited through well-established vapor phase methods that involve exposure of an ALD deposited metal-oxide layer to imidazole vapors at elevated temperatures (Stassen et al., 2015). Zinc, which is the most commonly used metal in ZIFs, has one of the highest EUV absorption cross sections of transition metals (Fallica et al., 2018) and can be easily deposited from the vapor phase. It has been shown that the irradiation of ZIFs can lead to increased stabilization in water (Conrad et al., 2018). Furthermore, the irradiation of ZIF-L, a single crystalline zinc and 2-methylimidazole based MOF, induces a solubility change and can produce both negative and positive tone patterns following electron beam patterning and etching in water and organic solvents, respectively (Miao et al., 2021).

Previous work on patterning of dry deposited inorganic-organic films has relied on the patterned growth of MOFs deposited via a two-step vapor phase process (Miao et al., 2022) or patterning of MOF films grown by exposure of ALD ZnO films to imidazole vapors (Tu et al., 2021), but both techniques result in patterned features that are limited by their crystallinity. In crystalline MOF films, the presence, growth, and reformation of discrete crystal domains tends to lead to increased line edge roughness, pattern heterogeneity, and limited resolution. For polymer resist films, the diameter of individual polymer molecules and larger aggregates similarly reduces pattern quality. The resolution of amorphous metal-imidazolate films should only be limited by the size of each tetrahedrally coordinated metal unit. Unlike polymer-based resists, the non-molecular amorphized material produced during irradiation is not expected to flow or agglomerate during heating or subsequent etching steps, resulting in a more consistent LER across a range of processing parameters.

It has been previously demonstrated that the incorporation of amorphous zinc inorganic-organic building units in a spin-coated film allows for high-resolution EUV patterns (15-nm line width) made via solution phase development (Xu et al., 2018). Without being bound to any one particular theory, it is thought that a homogeneous, vapor deposited amorphous film that is not limited by crystal size, grain boundaries, or anisotropy will provide the best potential for high resolution patterning. Amorphous metal-imidazolate films were selected for use in the Examples provided herein.

Further improvements in line resolution of traditional resist films are limited by pattern collapse and other mechanical stress issues, specifically capillary forces, resulting from the evaporation of solvent during the development step. The traditional use of solvent-based developers for photoresists also limits the aspect ratio of patterned features to around 3:1 height:width (Kulmala et al., 2016). To circumvent this limitation, interest has turned toward vapor phase “dry” processing techniques. Paired with established spin-on wet photoresists, dry development has typically taken the form of reactive ion etching using an oxygen or halogen plasma etch. Plasma-based etching methods may be undesirable as they necessitate high etch resistance of the unremoved photoresist material and the other materials present in the device (Pearton et al., 2000). To avoid plasma-based methods, compounds able to function as etchants owing to their chemical reactions with resists are desired. β-diketones have been explored for their use as CVD precursor ligands due to their formation of volatile organometallic complexes with a variety of 2+ metal ions. Several of these ligands, namely acetylacetone (acac) and hexafluoroacetylacetone (Hfac-H) have attracted interest as etchants for the removal of metal oxides, including zinc oxide (Rousseau et al., 1992). In these etching processes, the metal oxide is heated and given cyclic exposures of ligand and oxygen plasma which facilitates removal of the oxide with etch rates of several hundred nanometers per minute (Droes et al., 1998).

The use of β-diketones for synthesis and post synthetic modification of MOFs has been demonstrated in literature, however the use of β-diketones for removal or etching of MOFs is unprecedented (Huang et al., 2020, López-Cabrelles et al., 2019). A Zr-containing MOF, NU-1000, was reacted with acac, tfac, and/or Hfac-H to replace coordinating formate units in the MOF. This modification resulted in enhanced stability to cycled water adsorption/desorption and improved retention of catalytic activity after cycling (Liu et al., 2022). MOFs synthesized directly with Hfac as a ligand have been shown for Cu, with application as a material for CO₂ adsorption (Portales-Gil et al., 2022). Moreover, to the best of our knowledge, the use of Hfac-H and other similar type acetylacetonate compounds have never been proposed as selective gas phase etchants of ZIFs or metal-imidazolate films. We hypothesize that metal-imidazolate films exposed to irradiation will be unreactive upon exposure to β-ketonate vapors while non-irradiated areas should be as effectively etched as ZnO thin films because Zn(hfac)₂ complexes and imidazole ligands are easily removed volatile species at temperatures below 200° C.

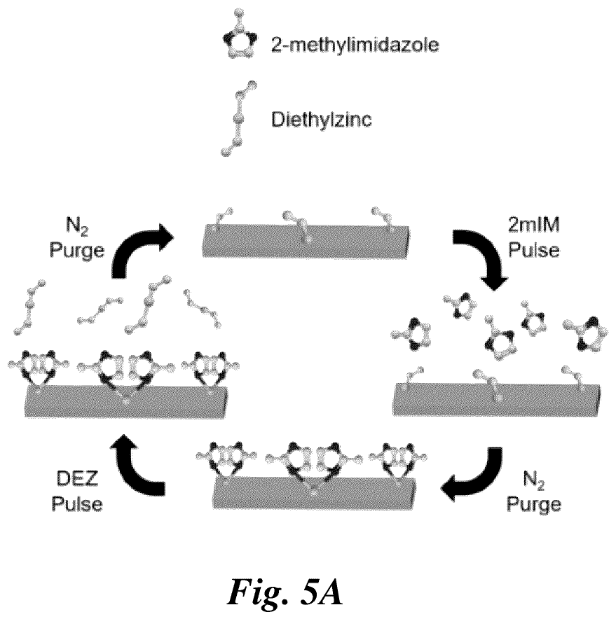

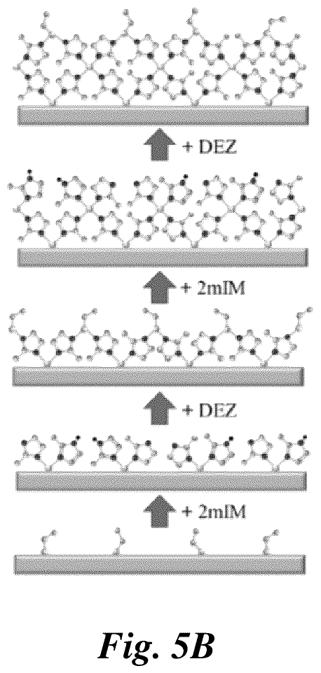

Development of dry-deposited amorphous metal-imidazolate films that can be removed by a vapor-phase β-ketonate etchant would combine the increased throughput and economical precursor usage of dry-deposition methods with the improved line resolution of amorphous thin films, while not being limited by pattern collapse, capillary forces, and other mechanical stress issues associated with solution-phase development. Without being bound to any one particular theory, it is thought that the following reaction scheme may describe the replacement of 2 mIm ligands and coordination of Hfac via protonation of 2 mIm by Hfac-H. The volatile Zn(Hfac)₂ and 2 mIm-H can then be removed from the reactor by heating and a dynamic vacuum purge (FIG. 5).

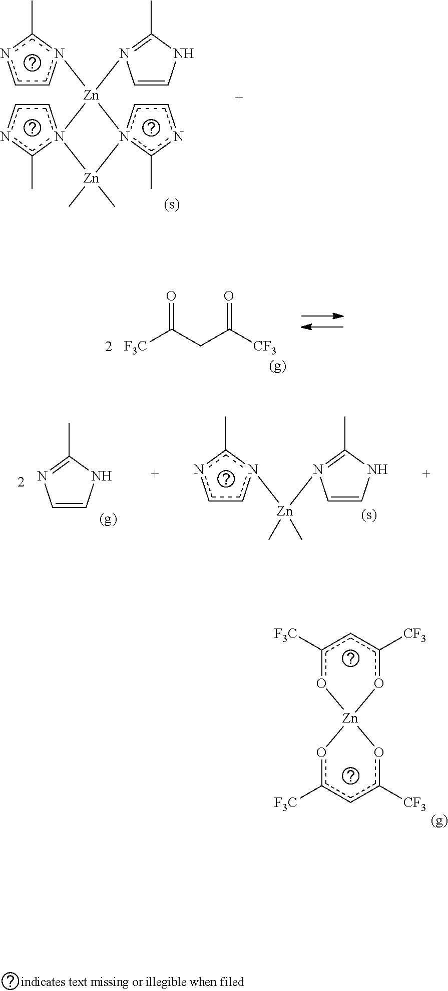

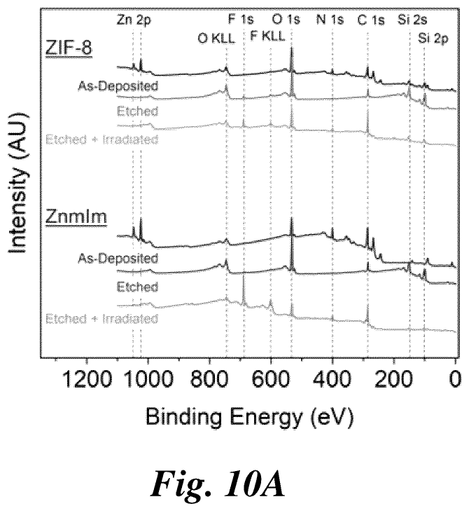

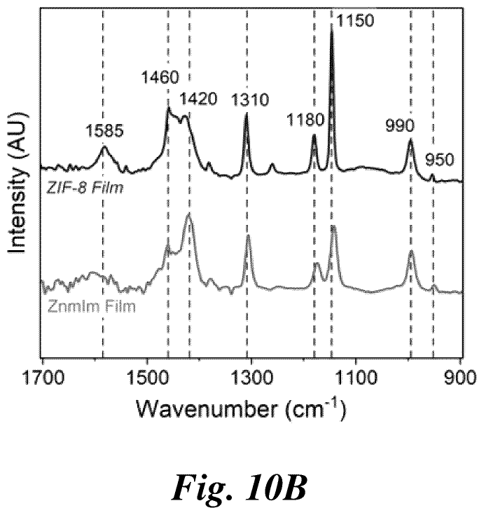

Successful ALD/MLD growth of amorphous metal-imidazolate films was demonstrated by ellipsometry. At 150° C., the observed growth rates of 0.15 nm/cycle and 0.21 nm/cycle for ZnmIm and ZnIca films, respectively, (FIG. 3) are well within the range of ALD/MLD growth rates for inorganic-organic films (Sundberg and Karppinen, 2014). The lack of long-range order and smoothness in the films was confirmed by XRD and AFM, respectively. Comparison of FTIR spectra of the deposited ZnmIm films (FIG. 10B) to those of crystalline ZIF-8 show highly similar peak positions, suggesting the presence of a zinc-imidazolate structure in the deposited films. XPS survey spectra of the deposited ZnmIm films (FIG. 10A) show the presence of C, N, O, and Zn matching the expected spectra for crystalline ZIF-8.

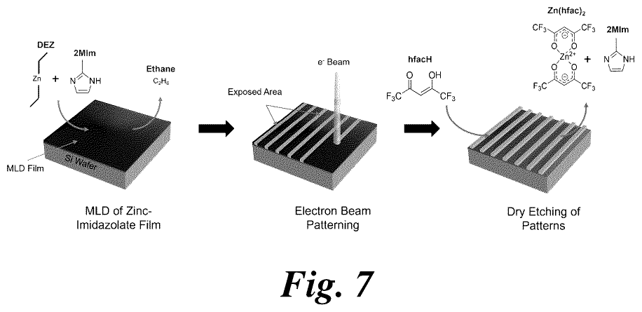

The exposure of patterned metal-imidazolate films to Hfac-H utilizing the process illustrated in FIG. 7 has demonstrated the facile removal of the non-irradiated areas at temperatures below 200° C. without the use of oxygen plasma. AFM (FIG. 6) and SEM (FIG. 8) characterization of the etched ZnmIm films demonstrate sub-150 nm pattern resolution with features as small as approximately 45 nm on silicon wafers with an imposed argon flow. XPS spectra of the irradiated films before and after etching demonstrate the complete removal of the zinc-imidazolate film as no Zn²⁺ or N remain on the silicon wafer, which would be expected for N-coordinated Zn²⁺ in the films (FIG. 10A). Pattern resolution is lower than expected based on the implemented pattern settings, but this is to be expected for several reasons. Foremost is reduced electron beam uniformity resulting from charging of the insulating imidazolate film, which is particularly severe for the 2 keV primary electron beam. Additionally, low energy secondary electrons responsible for chemical transformation in the resist have significant penetration depth, and backscattered electrons from the substrate are also expected to induce resist transformation far from the location of e-beam incidence. While these effects reduce the pattern resolution, they are not expected to have a significant impact on LER which should be defined primarily by physical properties of the film. TEM characterization of ZnmIm films deposited, patterned, and etched on silicon nitride TEM supports (FIG. 9) demonstrates critical feature dimensions as small as 30 nm while employing an acceleration voltage of 5 kV. Higher resolution patterning was demonstrated in FIG. 11 and FIG. 12, achieving line patterns 29 nm wide with 40 nm pitch on Si substrates and 22 nm wide with 30 nm pitch on silicon nitride TEM supports, respectively. Pattern transfer into the silicon substrate was also explored in FIG. 13, revealing sharp edge retention and minimal surface roughness. FIG. 13A demonstrates 70 nm of material removal with a 10 nm thick patterned zinc-imidazolate resist over 15 seconds of plasma etching, yielding an etch selectivity of at least 7:1 (silicon: ZnmIm). Patterning, dry development, and pattern transfer optimization is needed to realize the full potential of ZnmIm resists.

### 9.2 Summary

An all-vapor phase resist technology was demonstrated using a single step molecular layer deposition process of an amorphous zinc-imidazolate thin film and subsequent dry development of electron beam patterned films using Hfac-H, a model β-diketonate-type compound. This methodology produces a solvent free, EUV compatible process that allows for more cost-effective and high-resolution resist development.

### REFERENCES

All publications, patent applications, patents, and other references mentioned in the specification are indicative of the level of those skilled in the art to which the presently disclosed subject matter pertains. All publications, patent applications, patents, and other references are herein incorporated by reference to the same extent as if each individual publication, patent application, patent, and other reference was specifically and individually indicated to be incorporated by reference. It will be understood that, although a number of patent applications, patents, and other references are referred to herein, such reference does not constitute an admission that any of these documents form part of the common general knowledge in the art.
Conrad, S.; Kumar, P.; Xue, F.; Ren, L.; Henning, S.; Xiao, C.; Mkhoyan, K. A.; Tsapatsis, M., Controlling Dissolution and Transformation of Zeolitic Imidazolate Frameworks by using Electron-Beam-Induced Amorphization. Angew Chem Int Ed Engl 2018, 57 (41), 13592-13597.
Droes, S. R.; Kodas, T. T.; Hampden-Smith, M. J., Dry etching of ZnO films with hexafluoroacetylacetone. Advanced Materials 1998, 10 (14), 1129-+.
Fallica, R.; Haigema, J.; Wu, L.; Castellanos, S.; Brouwer, A. M.; Ekinci, Y., Absorption coefficient of metal-containing photoresists in the extreme ultraviolet. J Micro-Nanolith Mem 2018, 17 (2), 023505.
Hasan, R. M. M.; Luo, X., Promising Lithography Techniques for Next-Generation Logic Devices. Nanomanufacturing and Metrology 2018, 1 (2), 67-81.
Henke, B. L.; Gullikson, E. M.; Davis, J. C., X-Ray Interactions: Photoabsorption, Scattering, Transmission, and Reflection at E=50-30,000 eV, Z=1-92. Atomic Data and Nuclear Data Tables 1993, 54 (2), 181-342.
Huang, J. K.; Saito, N.; Cai, Y. C.; Wan, Y.; Cheng, C. C.; Li, M. L.; Shi, J. J.; Tamada, K.; Tung, V. C.; Li, S.; Li, L. J., Steam-Assisted Chemical Vapor Deposition of Zeolitic Imidazolate Framework. ACS Materials Letters 2020, 2 (5), 485-491.
Kuznetsova, N. A.; Malkov, G. V.; Gribov, B. G., Photoacid generators. Application and current state of development. Russian Chemical Reviews 2020, 89 (2), 173-190.
Li, L.; Liu, X.; Pal, S.; Wang, S.; Ober, C. K.; Giannelis, E. P., Extreme ultraviolet resist materials for sub-7 nm patterning. Chem Soc Rev 2017, 46 (16), 4855-4866.
Liu, J.; Anderson, R.; Schmalbach, K. M.; Sheridan, T. R.; Wang, Z.; Schweitzer, N. M.; Stein, A.; Mara, N. A.; Gomez-Gualdron, D.; Hupp, J. T., Insights into dual-functional modification for water stability enhancement of mesoporous zirconium metal-organic frameworks. Journal of Materials Chemistry A 2022, 10 (33), 17307-17316.
Lopez-Cabrelles, J.; Romero, J.; Abelian, G.; Gimenez-Marques, M.; Palomino, M.; Valencia, S.; Rey, F.; Minguez Espallargas, G., Solvent-Free Synthesis of ZIFs: A Route toward the Elusive Fe(II) Analogue of ZIF-8. J Am Chem Soc 2019, 141 (17), 7173-7180.
Manouras, T.; Argitis, P., High Sensitivity Resists for EUV Lithography: A Review of Material Design Strategies and Performance Results. Nanomaterials (Basel, Switzerland) 2020, 10 (8).
Marchon, B.; Carrazza, J.; Heinemann, H.; Sommjai, G. A., TPD and XPS studies of O₂, CO₂, and H₂O adsorption on clean polycrystalline graphite. Carbon 1988, 26 (4), 507-514.
Miao, Y.; Lee, D. T.; de Mello, M. D.; Ahmad, M.; Abdel-Rahman, M. K.; Eckhert, P. M.; Boscoboinik, J. A.; Fairbrother, D. H.; Tsapatsis, M., Solvent-free bottom-up patterning of zeolitic imidazolate frameworks. Nat Commun 2022, 13 (1), 420.
Miao, Y. R.; Tsapatsis, M., Electron Beam Patterning of Metal-Organic Frameworks. Chemistry of Materials 2021, 33 (2), 754-760.
Pearton, S. J.; Shul, R. J.; Ren, F., A Review of Dry Etching of GaN and Related Materials. MRS Internet Journal of Nitride Semiconductor Research 2014, 5 (1), 11.
Portolés-Gil, N.; Vallcorba, O.; Fraile-Sainz, J.; López-Periago, A. M.; Domingo, C.; Ayllón, J. A., One-dimensional metal-organic frameworks built by coordinating 2,4,6-tris(4-pyridyl)-1,3,5-triazine linker with copper nodes: CO₂ adsorption properties. Applied Organometallic Chemistry 2022, nla (n/a), e6930.
Rousseau, F.; Jain, A.; Kodas, T. T.; Hampden-Smith, M.; Farr, J. D.; Muenchausen, R., Low-temperature dry etching of metal oxides and ZnS via formation of volatile metal 3-diketonate complexes. J. Mater. Chem. 1992, 2 (8), 893-894.
Saifullah, M. S.; Tiwale, N.; Ganesan, R., Review of metal-containing resists in electron beam lithography: perspectives for extreme ultraviolet patterning. Journal of Micro/Nanopatterning, Materials, and Metrology 2022, 21 (4), 041402.
Silverman, P. J., Extreme ultraviolet lithography: overview and development status. J Microlith Microfab 2005, 4 (1), 011006.
Stassen, I.; Styles, M.; Grenci, G.; Gorp, H. V.; Vanderlinden, W.; Feyter, S. D.; Falcaro, P.; Vos, D. D.; Vereecken, P.; Ameloot, R., Chemical vapour deposition of zeolitic imidazolate framework thin films. Nat Mater 2016, 15 (3), 304-10.
Sundberg, P.; Karppinen, M., Organic and inorganic-organic thin film structures by molecular layer deposition: A review. Beilstein J Nanotechnol 2014, 5, 1104-36.

Tero, S. K.; Michaela, V.; Yasin, E. In A bottom-up pattern collapse mitigation strategy for EUV lithography, Proc. SPIE, 2016; p 97762N.
Tu, M.; Xia, B.; Kravchenko, D. E.; Tietze, M. L.; Cruz, A. J.; Stassen, 1.; Hauffi:nan, T.; Teyssandier, J.; De Feyter, S.; Wang, Z.; Fischer, R. A.; Marmiroli, B.; Amenitsch, H.; Torvisco, A.; Velasquez-Hernandez, M. J.; Falcaro, P.; Ameloot, R., Direct X-ray and electron-beam lithography of halogenated zeolitic imidazolate frameworks. Nat Mater 2021, 20 (1), 93-99.
Wu, B.; Kumar, A., Extreme ultraviolet lithography: A review. Journal of Vacuum Science & Technology B: Microelectronics and Nanometer Structures 2007, 25 (6), 1743.
Xu, H.; Sakai, K.; Kasahara, K.; Kosma, V.; Yang, K.; Herbol, H. C.; Odent, J.; Clancy, P.; Giannelis, E. P.; Ober, C. K., Metal-Organic Framework-Inspired Metal-Containing Clusters for High-Resolution Patterning. Chemistry of Materials 2018, 30 (12), 4124-4133.
Yamaguchi, T.; Namatsu, H.; Nagase, M.; Kurihara, K.; Kawai, Y., Line-edge roughness characterized by polymer aggregates in photoresists. SPIE:1999; Vol. 3678.

Although the foregoing subject matter has been described in some detail by way of illustration and example for purposes of clarity of understanding, it will be understood by those skilled in the art that certain changes and modifications can be practiced within the scope of the appended claims.

That which is claimed:

1. A method for vapor phase deposition of a non-crystalline thin film having a chemical formula of MLₙ on a substrate, wherein M is Zn⁺², L is a ligand, and n is 2, the method comprising:
pulsing a first precursor comprising an organometallic compound including the metal ion and a second precursor comprising the ligand sequentially into a flow-through reactor to create an organometallic vapor and a ligand vapor, and contacting the organometallic vapor and the ligand vapor with the substrate to form a non-crystalline thin film having the chemical formula of MLₙ on the substrate.

2. The method of claim 1, wherein the organometallic compound comprising the first precursor is selected from diethylzinc (DEZ), dimethylzinc, zinc(II) bis(1,1,1,5,5,5-hexafluoro-2,4-pentanedionate), zinc(II) bis(2,2,6,6-tetramethyl-3,5-heptanedionate), and zinc(II) bis(2,4-pentanedionate).

3. The method of claim 1, wherein the ligand comprises an imidazolate.

4. The method of claim 3, wherein the imidazolate is a derivative of 1,3-diazacyclopenta-2,4-diene having a chemical C₃N₂HR₃, wherein the R groups are positioned at the 1, 4, and 5 positions of 1,3-diazacyclopenta-2,4-diene and are each independently selected from —H, —CH₃, —CH₂CH₃, —Cl, —Br, —I, —C₄H₄, and —CHO.

5. The method of claim 4, wherein the imidazolate is a conjugate base of an imidazole selected from: 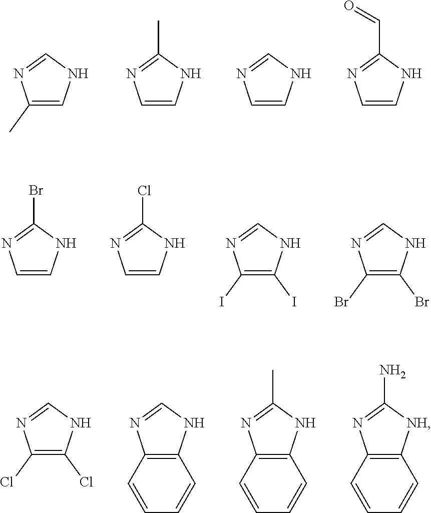
and combinations thereof.

6. The method of claim 1, wherein the flow-through reactor is maintained at a temperature range selected from between about 100° C. to about 250° C., between about 125° C. to about 175° C., and about 150° C.

7. The method of claim 1, further comprising purging the flow-through reactor with an inert gas between sequential pulses of the first precursor and the second precursor to remove one or more byproducts, one or more unreacted precursors, and combinations thereof.

8. The method of claim 7, wherein the inert gas has a flow rate of about 10 standard cubic centimeters per minute or a space time of 0.1-2 s.

9. The method of claim 7, wherein the inert gas comprises Argon.

10. The method of claim 1, wherein the flow-through reactor is maintained at a pressure between about 100 mTorr to about 1,000 mTorr.

11. The method of claim 1, wherein the first precursor has a pulse length of about 50 ms and the second precursor has a pulse length between about 50 ms to about 1000 ins.

12. The method of claim 1, wherein the first precursor has a purge length between about 5 s to about 60 s and the second precursor has a purge length between about 10 s to about 90 s.

13. The method of claim 1, wherein the thin film comprises a zinc-imidazolate film.

14. The method of claim 1, wherein the zinc-imidazolate film comprises a Zn⁺² metal ion and a 2-methylimidazole (2 mIm) ligand.

15. A method for patterning a thin film on a substrate, the method comprising:
(a) providing a thin film prepared by the method of claim 1;
(b) loading the thin film into a high vacuum chamber; and/or
(c) patterning the thin film with direct write patterning, maskless patterning, or shadow mask patterning.

16. The method of claim 15, further comprising irradiating the thin film with an electron source, an x-ray source, an extreme ultraviolet source, or other radiation source capable of producing secondary electrons.

17. The method of claim 15, comprising patterning by an electron beam having:
(a) an acceleration voltage with a range from about 2 keV to about 200 keV;
(b) a current with a range from about 6.3 pA to about 1.2 nA; and/or
(c) a dosage having a range from about 0.01 mC cm⁻² to about 50 mC cm².

18. The method of claim 16, wherein the thin film is exposed to radiation at a dwell time of about 1 μs.

19. The method of claim 15, further comprising varying a pass (scan) number to obtain a desired dosage for each pattern.

20. The method of claim 15, wherein the patterning is performed:
(a) by shadow mask patterning with an electron energy of about 2 keV;
(b) at an emission current between about 0.15 μA and about 4 μA; and/or
(c) for a duration ranging from about one minute to about one hour.

21. A method for etching a thin film on a substrate, wherein the thin film comprises a thin film of any one of claim 1, the method comprising reacting the thin film with a volatile reagent to produce a volatile organometallic product and an organic product described by the formula A+B=>C+D where A represents the metal/ligand containing film, B represents an volatile molecular etchant, C represents a volatile coordination complex of the etchant and metal, and D represents the volatile ligand originally contained in the film.

22. The method of claim 21, wherein the etchant B comprises one or more β-diketonates.

23. The method of claim 22, wherein the one or more β-diketonates is selected from: 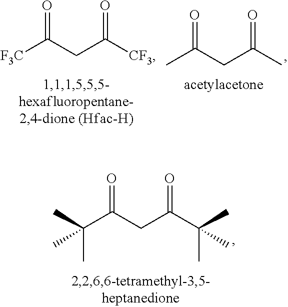
and combinations thereof.

24. The method of claim 21, wherein the etchant is selected from oxygen-containing plasma, halogen-containing plasma, nitrogen-containing plasma, NOx, HCl, and combinations thereof.

25. The method of claim 21, wherein the thin film is exposed to the etchant for a period of time between about 1 minute and about 60 minutes.

26. The method of claim 25, wherein the thin film is sequentially exposed to the etchant for a period of time between about 1 minute and about 15 minutes followed by purging with an inert gas comprising a combination of one or more of helium, neon, argon, krypton, nitrogen, or xenon, for a period of time between about 1 minute and about 15 minutes.

27. The method of claim 21, comprising heating the thin film to a temperature having a range between about 25° C. to about 400° C.

28. The method of claim 21, further comprising combining the etchant with an inert gas or plasma, an oxidizing gas or plasma, a halogen-containing gas or plasma, and combinations thereof.

29. The method of claim 28, wherein the inert gas or plasma is selected from helium, neon, argon, krypton, nitrogen, xenon, and combinations thereof.

30. The method of claim 28, comprising contacting the etchant, oxidizing gas or plasma, halogen-containing gas or plasma, inert gas, or combinations thereof, with the thin film:
(a) within a temperature range of between about 25° C. to about 400° C.;
(b) for an exposure time having a range between about 1 minute to about 120 minutes;
(c) at a pressure of about 10×10⁻³ mbar or less; and/or
(d) at an etchant partial pressure of about 1 mbar to about 100 mbar.

31. A non-crystalline thin film having a chemical formula of MLₙ, wherein M is a metal ion, L is a ligand, and n is a number of ligands.

32. The non-crystalline thin film of claim 31, wherein the ligand comprises an imidazolate.

33. The non-crystalline thin film of claim 32, wherein the imidazolate is a derivative of 1,3-diazacyclopenta-2,4-diene having a chemical C₃N₂HR₃, wherein the R groups are positioned at the 1, 4, and 5 positions of 1,3-diazacyclopenta-2,4-diene and are each independently selected from —H, —CH₃, —CH₂CH₃, —Cl, —Br, —I, —C₄H₄, and —CHO.

34. The non-crystalline thin film of claim 32, wherein the imidazolate is a conjugate base of an imidazole selected from: 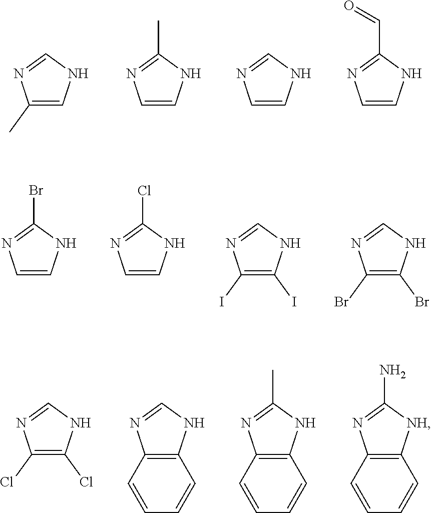
and combinations thereof.

35. The non-crystalline metal-imidazolate thin film of claim 32, wherein the ligand comprises 2-methylimidazole (2 mIm).

36. The non-crystalline thin film of claim 31, wherein the thin film comprises a zinc-imidazolate.

37. The non-crystalline thin film of claim 31, wherein a pattern of the thin film has a:
(a) line edge roughness of less than 1 nm;
(b) feature resolution of about 5 nm; and/or
(c) roughness of less than about 10 nm.

38. The non-crystalline thin film of claim 31, wherein the thin film lacks a long-range order, as evidenced by XRD.

39. The non-crystalline thin film of claim 31, wherein the thin film has a thickness from about 2 nm to about 500 nm.

40. The non-crystalline thin film of claim 41, wherein a pattern of the thin film has a:
(a) feature thickness between about 2 and about 50 nanometers;
(b) a spacing of about 20-30 nanometers or more;
(c) line thickness of less than about 80 nm;
(d) pitch of about 20 nanometers or more.

41. An article comprising the non-crystalline thin film of claim 31.

42. The article of claim 41, wherein the article is selected from an extreme ultraviolet lithography (EUVL) resist and a microelectronic device.

43. The article of claim 41, further comprising a material produced by irradiation of the thin film that is not removed by a subsequent etching process.

44. The article of claim 43, wherein the article is selected from a structural material, a dielectric barrier, and a photomask.
